(19) United States
(12) Patent Application Publication
(10) Pub. No.: US 2024/0274398 A1
(43) Pub. Date: Aug. 15, 2024

(54) METHOD OF GLOBAL AND LOCAL OPTIMIZATION OF IMAGING RESOLUTION IN A MULTIBEAM SYSTEM

(71) Applicant: Carl Zeiss MultiSEM GmbH, Oberkochen (DE)

(72) Inventor: Christof Riedesel, Aalen (DE)

(21) Appl. No.: 18/643,625

(22) Filed: Apr. 23, 2024

Related U.S. Application Data
(63) Continuation of application No. PCT/EP2022/073756, filed on Aug. 26, 2022.

(30) Foreign Application Priority Data
Oct. 25, 2021 (DE) 10 2021 211 965.4

(51) Int. Cl. H01J 37/153

(52) U.S. Cl. CPC H01J 37/153; H01J 2237/1532; H01J 2237/1534; H01J 2237/2826

(57) ABSTRACT

A multi-beam charged particle microscope configured determines and compensates wave front aberrations. With a variation element, the wave-front aberration amplitudes are indirectly determined and transformed in normalized sensitivity units. It is possible to compensate the wave-front aberrations with a compensation element which is different from the variation element. The normalized sensitivity units can for example be determined an improved calibration method.

### CROSS-REFERENCE TO RELATED APPLICATIONS

The present application is a continuation of, and claims benefit under 35 USC 120 to, international application No. PCT/EP2022/073756, filed Aug. 26, 2022, which claims benefit under 35 USC 119 of German Application No. 10 2021 211 965.4, filed Oct. 25, 2021. The entire disclosure of each these applications is incorporated by reference herein.

### FIELD

The disclosure is applicable to multi-beam charged particle systems and is especially suitable for the operation of multi-beam charged particle systems which are comprising at least an array of charged particle optical elements as well as global charged particle components.

### BACKGROUND

With the continuous development of ever smaller and more sophisticated microstructures such as semiconductor devices there is a desire for further development and optimization of planar fabrication techniques and inspection systems for fabrication and inspection of the small dimensions of the microstructures. Development and fabrication of the semiconductor devices involved for example design verification of test wafers, and the planar fabrication techniques involve process optimization for reliable high throughput fabrication. In addition, recently the analysis of semiconductor wafers for reverse engineering and customized individual configuring of semiconductor devices is used. High throughput inspection tools for the examination of the microstructures on wafers with high accuracy are therefore desired.

Typical silicon wafers used in manufacturing of semiconductor devices have diameters of up to 12 inches (300 mm). Each Wafer is segmented in 30-60 repetitive areas (“Dies”) of about up to 800 sq mm size. A semiconductor device comprises a plurality of semiconductor structures fabricated in layers on a surface of the wafer by planar integration techniques. Due to the fabrication processes involved, semiconductor wafers have typically a flat surface. The feature size of the integrated semiconductor structures extends between few micrometers (μm) down to the critical dimensions (CD) of 5 nanometers (nm), with even decreasing features sizes in near future, for example feature sizes or critical dimensions (CD) below 3 nm, for example 2 nm, or even below 1 nm. With the small structure sizes mentioned above, defects of the size of the critical dimensions are identified in a very large area in a short time.

A recent development in the field of charged particle microscopes CPM is the multi-beam charged particle microscope. A multi beam charged particle beam microscope is disclosed, for example, in U.S. Pat. No. 7,244,949 BB and in U.S. Pat. No. 10,896,800 BB. In such a multi beam charged particle microscope, such as a multi beam scanning electron microscope, a sample is irradiated by an array of electron beamlets, comprising for example 4 up to 10000 electron beams, as primary radiation, whereby each electron beam is separated by a distance of 1-200 μm from its next neighboring electron beam. For example, an MSEM has 100 separated electron beams or beamlets, arranged on a hexagonal array, with the electron beamlets separated by a distance of about 10 μm. The plurality of primary charged particle beamlets is focused by an objective lens on a surface of a sample under investigation, for example a semiconductor wafer fixed on a wafer chuck, which is mounted on a movable stage. During the illumination of the wafer surface with primary charged particle beamlets, interaction products, e.g. secondary electrons, originate from the plurality of intersection points formed by the focus points of the primary charged particle beamlets, while the amount and energy of interaction products depend on the material composition and topography of the wafer surface. The interaction products form a plurality of secondary charged particle beamlets, which is collected by the objective lens and guided onto a detector arranged at a detector plane by a projection imaging system of the multi-beam inspection system. The detector comprises a plurality of detection areas with each comprising a plurality of detection pixels and detects an intensity distribution for each of the plurality of secondary charged particle beamlets and an image patch of for example 100 μm×100 μm is obtained.

Some known multi-beam charged particle microscopes comprise a sequence of electrostatic and magnetic elements. At least some of the electrostatic and magnetic elements are adjustable to adjust focus position and stigmation of the plurality of secondary charged particle beams. As an example, U.S. Ser. No. 10/535,494 proposes a re-adjustment of the charged particle microscope, if the detected intensity distribution of a focus of a secondary charged particle beamlet deviates from a predetermined intensity distribution. An adjustment is achieved, if the detected intensity distribution is in accordance with the predetermined intensity distribution. A global displacement or deformation of the intensity distributions of secondary charged particle beamlets allows to draw conclusions on topography effects, the geometry, or a tilt of the sample, or charging effects of the sample. U.S. Pat. No. 9,336,982 B2 discloses a secondary charged particle detector with a scintillator plate to convert secondary charged particles to light.

US 2019/0355544 A discloses a multi-beam charged particle microscope with an adjustable projection system to compensate charging of a sample during scan. Therefore, the projection system is configured with fast, electrostatic elements to maintain a proper imaging of secondary charged particle beamlets from the sample to the detectors. Some known multi-beam charged particle microscopes comprise detection systems to facilitate the adjustment.

It is generally desirable to change the imaging settings of a charged particle microscope. A method of changing image acquisition settings of a multi-beam charged particle microscope from a first imaging setting to a different, second imaging setting is described by U.S. Pat. No. 9,799,485 B2.

In charged particle microscopes for wafer inspection, however, it is desired to achieve an imaging resolution with high reliability and high repeatability. With a multi-beam system, an image is obtained by a plurality of individual charged particle beamlets, each forming an individual image segment. Even after compensation of a field curvature, each image segment imaged with an individual beamlet is obtained with a specific resolution, which generally depends on the beam quality of the corresponding beamlet. The resolution of each image segment can deviate from a predetermined imaging resolution, for example they can be exceeding a resolution threshold, and the resolution in each image segment can be different for each different beamlet. This can be caused by field-dependent aberrations of the (global) illumination system. In addition, the resolution of the multi-beam system can change over time or depend on an inspection site of an object under investigation. The imaging resolution of multi-beam systems can be deteriorated by individual aberrations of each beamlet.

Generally, it is a problem of the disclosure to provide a multi-beam charged particle inspection system for wafer inspection with a mechanism to enable high precision and high-resolution image acquisition with high reliability over the plurality of image segments obtained by a plurality of charged particle beamlets. It is a further problem of the disclosure to monitor and to compensate individual aberrations of each beamlet of the multi-beam system and to provide an equally corrected stigmatic imaging condition for each beamlet.

### SUMMARY

The present disclosure seeks to provide a charged particle system and operation method of a charged particle system that allow high throughput examination of integrated semiconductor features with the resolution of at least the critical dimension during the development or during manufacturing or for reverse engineering of semiconductor devices. It may be possible to acquire high resolution images for a set of specific locations on a wafer, for example for so called process control monitors PCMs or critical areas only.

The disclosure seeks to provide a multi-beam charged particle inspection system with a mechanism to allow high precision and high-resolution image acquisition with high reliability. The disclosure seeks to provide a multi-beam charged particle inspection system with a mechanism to monitor and control the resolution of each image segment for each of the plurality of primary charged particle beamlets. The disclosure seeks to provide a multi-beam charged particle inspection system with a mechanism to maintain high resolution and high image contrast during image acquisition with high reliability of a sequence of image patches.

Embodiments of the disclosure involve a multi-beam charged particle microscope comprising at least one global compensator and an array element of compensators configured for the determining and compensating of wave-front aberrations of a plurality of primary charged particle beamlets. The disclosure provides a method for determining the plurality of wave-front aberrations of each of the plurality of primary charged particle beamlets. The disclosure further provides a method for compensating the plurality of wave-front aberrations of each of the plurality of primary charged particle beamlets. The disclosure further provides a method of monitoring of the plurality of wave-front aberrations of each of the plurality of primary charged particle beamlets during a wafer inspection task. The disclosure can provide a method of operating a multi-beam charged particle microscope with low aberrations of each of a plurality of primary charged particle beamlets. Embodiments of the disclosure provide a method of operating a multi-beam charged particle microscope in which an inspection task complies with desired throughput and resolution properties of a wafer inspection task.

The disclosure further provides a multi-beam charged particle microscope configured for performing the method of operating the multi-beam charged particle microscope, optionally with high throughput and low aberrations. The multi-beam charged particle microscope according to the disclosure can comprise an array element of compensators, comprising a plurality of compensators for compensation of a wave-front aberration of each of the plurality of primary charged particle beamlets. The multi-beam charged particle microscope according to the disclosure can further comprise at least one of a variation element or a global compensator. The wave-front aberrations of at least the subset of primary charged particle beamlets can be determined by variation of beam shapes of at least a subset of primary charged particle beamlets by at least one of the variation element, the global compensator, or the array element of compensators. According to an aspect of the disclosure, the sensitivities of the array element of compensators, the global compensator and/or the variation element are determined in normalized sensitivity units. From the wave-front aberrations in normalized sensitivity units, a control signal can be computed in normalized sensitivity units for the compensation of the wave-front aberrations. The control signal can be provided to the global compensator and/or the array element of compensators. With the determination of wave-front errors and control signals in normalized sensitivity units, it is possible to determine a wave-front error with a first element and to compensate the wave-front error with a second element, which is different from the first element. The first element can be any of the array element of compensators, the global compensator or the variation element. The second elements can comprise the array element of compensators, the global compensator, or both. With the determination of wave-front errors and control signals in normalized sensitivity units, a fast compensation of wave-front aberrations for the desired throughput of a wafer-inspection task can be possible. With the improved determination of the wave-front aberrations in normalized sensitivity units, the wave-front aberrations are minimized with higher precision, and a higher imaging performance such as higher resolution and higher imaging contrast can be achieved. Furthermore, a variation of wave-aberrations throughout the plurality of primary charged particle beamlets can be minimized.

In a first embodiment, a multi-beam charged particle microscope according to the disclosure is described. A multi-beam charged particle system comprises at least an array of charged particle optical elements as well as global elements. The global charged particle elements such as an objective lens or a beam divider are a first source of aberrations. The array of charged particle optical elements or array-optical element are a second source of aberrations. The multi-beam charged particle microscope according to the disclosure comprise an array element of compensators, comprising a plurality of compensators for compensating of a wave-front aberration of each of the plurality of primary charged particle beamlets, and at least one of a variation or a global compensator element. The multi-beam charged particle microscope further comprises a control unit with a memory and a processor, configured to perform the methods of determining, monitoring and compensating a plurality of wave-front aberrations of the plurality of primary charged particle beamlets in short time. The control unit is configured to derive the wave-front-aberration by variation of beam shapes of at least a subset of primary charged particle beamlets by variation of at least one of the variation element, the global compensator, or the array element of compensators in normalized sensitivity units. The control unit is configured to derive a control signal for compensating the wave-front errors in normalized sensitivity units and to provide the control signal to the global compensator element and/or the array element of compensators.

In an example, the multi-beam charged particle microscope of the disclosure further comprises a beam divider for dividing the beam-path of a plurality a primary charged particle beamlets from a beam-path of a plurality of secondary electron beamlets and a detection system for detecting the plurality of secondary electron beamlets. The detection system comprises a projection imaging system for imaging the plurality of secondary electron beamlets on a detector. The control unit is configured to change or vary the wave-front errors of at least a subset of the plurality of primary charged particle beamlets with one of the variation element, the global compensator element and/or the array element of compensators. With the detector, a plurality of image series is obtained, and the control unit is configured to derive the plurality of wave-front errors of at least a subset of the plurality of primary charged particle beamlets from the plurality of image series. The control unit is thereby configured to transform the result from the data analysis of the plurality of image series according to the plurality of wave-front errors in normalized sensitivity units. The control unit is further configured to derive a control signal for the compensation of the wave-front errors of all of the plurality of primary charged particle beamlets in normalized sensitivity units. The control unit is configured to provide the control signal to at least one of the global compensator element and/or the array element of compensators. The global compensator element and/or the array element of compensators are configured to individually or jointly compensate a wave-front aberration of a primary charged particle beamlet. Therefore, the control signal for each individual compensation element is calibrated with predetermined calibration parameters like offset and gradient of a calibration transfer curve.

A multi-beam charged particle microscope according to the first embodiment can comprise a multi-beam generating unit for generating a plurality of J primary charged particle beamlets. It can further comprise an array of compensation elements, a global compensation element and/or a variation element. A control unit of the multi-beam charged particle microscope can be configured to adjust the multi-beam charged particle microscope at a setting point and to vary a wavefront aberration amplitude of each or the plurality of primary charged particle beamlets with the variation element. It can be further configured to determine the wavefront aberration amplitudes A(j) of each or the plurality of J primary charged particle beamlets at the setting point and to determine a first or global component AG1 and a second or residual component Ares(j) of a field dependency of the wave front aberration amplitudes A(j) of the plurality of J primary charged particle beamlets. The control unit can be further configured to compensate the global component AG1 by providing a control signal to the global compensation element and to compensate the residual components Ares(j) by providing a plurality of control signals to the array of compensation elements. The global compensation element can be a multipole element comprising at least a first layer of multiple electrostatic or magnetic poles, and the global component AG1 of the field dependency of the wave front aberration amplitudes corresponds to a low order field dependency of the wave front aberration amplitudes effected by the global compensation element. The array of compensator components can comprise at least a first layer with a plurality of J apertures and multiple electrostatic poles arranged in the circumference of each aperture; and wherein the residual components Ares(j) of the field dependency of the wave front aberration amplitudes is corresponding to a residual wave front aberration, which cannot be compensated with the global compensation element. The control unit can be further configured to transform the wavefront aberration amplitudes determined by the variation of the variation element into normalized sensitivity units and to determine from the residual component of the wavefront aberration amplitudes in normalized sensitivity units the plurality of control signals for the array of compensation elements. The control unit of the multi-beam charged particle microscope can be further configured to determine the control signal for the global compensation elements from the global component of the wavefront aberration amplitude AG1 in normalized sensitivity units. The variation element can be given by a deflection scanner, or a magnetic correction element of the multi-beam charged particle microscope, but in another example, the variation element can also be identical to the global compensation element of the multi-beam charged particle microscope. There can also be a plurality of for example two variation elements and a plurality, for example two global compensation elements with different low-order field dependencies corresponding to a wave-front aberration amplitudes AG1 and AG2. During use, the setting point can deviate from a design setting point and due to a rotation of the primary charged particle beamlets in magnetic fields, the setting point can comprise a deviation of a predetermined rotation of the raster configuration of the plurality of primary charged particle beamlets between the coordinate systems of the image plane, the array of compensator components, the global compensation element and/or the variation element. The control unit is therefore configured to compensate a rotation difference of the wave-front aberration between the compensation elements and/or the variation element.

In a second embodiment of the disclosure, a method for determining the plurality of wave-front aberrations of each of the plurality of primary charged particle beamlets in normalized sensitivity units is provided. According to the method, a plurality of wave-front aberrations of at least a subset of the plurality of primary charged particle beamlets is determined. In an example, the individual wave-front aberrations of each beamlet are determined by variation of a beam property of each beamlet by a variation element of the multi-beam charged particle microscope. The method comprises the determination of a first and a second contribution to a wave-front error. The first contribution corresponds to a functional dependency of the wave-front error of plurality of primary charged particle beamlets.

In a method of determining a plurality of wave-front aberration amplitudes of a multi-beam charged particle microscope according to the second embodiment, multi-beam charged particle microscope can be first adjusted or set to a setting point of an inspection task. In a second step, the wave front aberration of a plurality of J primary charged particle beamlets can be varied by providing a series of at least SI=3 different variation control signal SV(i=1 . . . SI) to a variation element and measuring a plurality of contrast values C(j,i) at each variation control signal SV(i=1 . . . SI) for each of the plurality of J primary charged particle beamlets. From the plurality of contrast values C(j,i), a plurality contrast curves C(j=1 . . . J) is determined for each of the plurality of J primary charged particle beamlets. The plurality of J wave-front aberration amplitudes in normalized sensitivity units A(j=1 . . . J) at the setting point can be derived from the plurality of contrast curves C(j=1 . . . J). The method can include a computation of a parabolic, hyperbolic or polynomial approximation to the i=1 . . . SI contrast values C(j,i) for each of the plurality of J primary charged particle beamlets. In a first example, each of plurality of J wave-front amplitudes A(j) in normalized sensitivity units is determined from a variation control signal SV(maxC(j)) at a maximum contrast value maxC(j) divided by a normalized range RV of the variation element. The method can further comprise the step of determining the normalized range RV by determining a maximum and a minimum control signal SV used to achieve a predetermined variation of the image contrast of at least one of the plurality of primary charged particle beamlets. In a second example, each of plurality of J wave-front amplitudes A(j) in normalized sensitivity units is determined from a parabolic coefficient KV(j) of the contrast curve C(j) in the proximity of a local maximum or minimum of the contrast curves C(J).

The method can further comprise the transformation of the wave-front aberration amplitudes into a wave-front aberration amplitude vector. During use, the setting point can deviate from a design setting point and due to a rotation of the primary charged particle beamlets in magnetic fields, the setting point can comprise a deviation of a predetermined rotation of the raster configuration of the plurality of primary charged particle beamlets between the coordinate systems of the image plane, the array of compensator components, the global compensation element and/or the variation element. In an example of the method according to the second embodiment, the deviation of a predetermined rotation of the raster configuration of the plurality of primary charged particle beamlets between a coordinate system of an image plane, an array of compensator components, a global compensation element and/or the variation element can be considered by multiplication of the wave-front aberration amplitude vector with a rotation matrix M.

In a third embodiment of the disclosure, a method for compensating the plurality of wave-front aberrations of each of the plurality of primary charged particle beamlets is provided.

With the global compensator or the array element of compensators, a wave-front aberration of each of the plurality of primary charged particle beamlets is minimized. A method of compensating a plurality of wave-front aberrations of a multi-beam charged particle microscope at a setting point can comprise the step of receiving a plurality of J wave-front aberration amplitudes A(j=1 . . . J) of a plurality of J primary charged particle beamlets in normalized sensitivity units. It can further comprise the step of determining a global component of amplitude AG1 in normalized sensitivity units, the global component having a predetermined field dependency of the plurality of J wave-front aberration amplitudes A(j) of a global compensation element. It can further comprise the step of determining a residual component of a plurality of residual wave-front amplitudes Ares(j) in normalized sensitivity units. It can further comprise the steps of transforming the global component in a global correction signal GCS and transforming the residual component in a plurality of local compensation signals LCS(j). The global correction signal GCS can be provided to a global compensating element; and the plurality of local compensation signals LCS(j) can be provided to an array of compensation elements. In an example, the method according to the third embodiment can comprise a step of determining the plurality of J wave-front aberration amplitudes A(j). The step of determining can be performed according to the method of the second embodiment of the disclosure.

As illustrated in the embodiments, different normalized sensitivity units are possible, for example the scaling in ranges RV, or RC, or the scaling according to the parabolic sensitivity constants KV and KC. Other scalings in normalized sensitivity units are possible as well. With a consistent selection of normalized sensitivity units to be applied in the determination step and in the compensation step it is possible to transfer measurement values from a determination step directly to a compensation step, and it is possible to transfer compensation signals from global compensators to compensator elements of an array of compensation elements.

In a fourth embodiment of the disclosure, a method for monitoring the plurality of wave-front aberrations of the plurality of primary charged particle beamlets is provided. According to the fourth embodiment, a method can comprise a monitoring of a wave-front aberration of the multi-beam charged particle microscope during an inspection task. The monitoring can be performed by a model-based control based on a predetermined model of the multi-beam charged particle microscope and secondary, indirect monitoring parameters. The method utilizing model-based control can trigger the determination of the plurality of J wave-front aberration amplitudes according to the second embodiment, when a predicted image contrast according to the predetermined model is below a predetermined threshold. The monitoring can comprise monitoring an image contrast of a plurality of digital images received during an inspection task and triggering the receiving of the plurality of J wave-front aberration amplitudes when an image contrast is below a predetermined threshold.

In a fifth embodiment of the disclosure, a method of determining and calibrating the normalized sensitivity units of a wave-front aberrations of the plurality of primary charged particle beamlets is provided.

According to a first example of the fifth embodiment, a method of calibrating a charged particle optical element of a multi-beam charged particle microscope can comprise the steps of: (a) varying the wave front aberration of a plurality of J primary charged particle beamlets by providing a series of at least SI=3 different control signal SC(i=1 . . . SI) to the charged particle optical element; (b) measuring a plurality of contrast values C(j=1 . . . J, i=1 . . . SI) at each different control signal SC(i=1 . . . SI) for each of the plurality of J primary charged particle beamlets; (c) determining a plurality contrast curves C(j=1 . . . J, SC) from the plurality of contrast values C(j,i) for each of the plurality of J primary charged particle beamlets; (d) determining an extremal value maxC(j) and the control signal SC(maxC(j)) corresponding to the extremal value maxC(j) of each of the contrast curves C(j,SC); and (e) determining a plurality of variations of the wave-front amplitudes A(j) effected by the charged particle optical element in normalized sensitivity units. The charged particle optical element can be any element, such as a global compensator or a compensator element of an array of compensator elements, or a variation element. In an example, the plurality of variations of the wave-front amplitudes A(j) is obtained in normalized sensitivity units by A(j)=SC(maxC(j))/RC, with RC being a normalized range of the charged particle optical element, corresponding to the difference between a maximum and a minimum control signal SC required to achieve a predetermined variation of the image contrast C(j) for at least one of the plurality of J primary charged particle beamlets. In another example, the plurality of variations of the wave-front amplitudes A(j) is obtained in normalized sensitivity units by A(j)=SIGN(j)*2 KV(j)*SC(maxC(j)), with the parabolic constant KC(j) of an approximation to a contrast curve C(j=1 . . . J,SC) in proximity of the extremal value max(C(j,SC)). Both examples of normalized sensitivity units are equivalent, but it is desirable to consistently select one normalization method for example according to the selection of the third embodiment of the invention for the determination as well as the compensation. The plurality of variations of the wave-front amplitudes A(j) of the charged particle optical element can then be stored in normalized sensitivity units in a memory of a control unit of the multi-beam charged particle microscope.

According to a second example fifth embodiment, a method of determining a wavefront aberration in absolute units can be given. For each of the plurality of J primary charged particle beamlets, a wave-front detection pattern can be provided in an image plane of the multi-beam charged particle microscope. Each wave-front detection pattern can comprise a plurality of repetitive features oriented at different rotation angles a. A plurality of measurement of the wave-front detection patterns can be performed in a focus series with NQ focus steps q=1 . . . NQ and a plurality of contrast values C(j,q;α) can be determined. The plurality of contrast curves C(j;α) can be approximated as a function of focus position for each of the beamlets j=1 . . . J and each of the rotation angles a and the maximum values maxC(j;α) can be determined for each of the contrast curves C(j;α). A symmetrical wave-front aberration A(j) with a rotational symmetry of even order for each of the beamlets can be determined from the maximum difference of two focus-positions of two maximum values maxC(j;α) and maxC(j;α−90) of two repetitive features oriented at 90° with respect to each other. A symmetrical wave-front aberration A(j) with a rotational symmetry of even order can for example be given by an astigmatism. The method may further comprise the determination of a plurality of relative image displacement dr(j;α) through focus of each of the plurality of repetitive features. From the plurality of relative image displacement dr(j;α), an asymmetric wave-front aberration with a rotational symmetry of odd order for each of the beamlets can be derived. An asymmetric wave-front aberration with a rotational symmetry of odd order can for example be coma.

Other features of the embodiments of the present disclosure will become apparent from the following description in conjunction with the accompanying drawings. The disclosure, however, is not limited to the embodiments and examples, but also comprises variations, combinations, or modifications thereof. Other embodiments of the disclosure will be apparent to those skilled in the art from consideration of the specification and practice of the disclosure disclosed herein. For example, the apparatus and the usage of the method defined in this application is not limited to the usage of an electron beam as charged particle. Rather, any particle beam can be used. Examples of alternative particle beams are ion beams, metal beams, molecular beams. Further, the application of the disclosure is not limited to the inspection of semiconductor wafer but is in general applicable to objects or samples involved in semiconductor manufacturing, including lithography masks. The word “wafer” shall thus not be limited to semiconductor wafers but shall include lithography masks for wafer printing. The disclosure is however also applicable to other Nano-structured objects including such as photonic crystals and meta-materials, and to the investigation of biological tissue and minerals.

### BRIEF DESCRIPTION OF THE DRAWINGS

FIG. 1 illustrates a multi-beam charged particle microscope according to the first embodiment.

FIG. 2 shows a raster configuration of a multi-beam charged particle microscope and the image patches of an inspection task.

FIGS. 3A-3B illustrate a shape of an astigmatic electron beamlet and a corresponding contrast curve through focus distance z.

FIG. 4 illustrates an array of compensator element.

FIGS. 5A-5B illustrate a field dependency of a wave-front aberration amplitude in normalized units of the plurality of primary charged particle beamlets in a hexagonal raster configuration.

FIG. 6 illustrates a method of determination of wave-front amplitudes according to the second embodiment of the disclosure.

FIG. 7 illustrates a contrast curve through a change of a control parameter SV of a variation element.

FIG. 8 illustrates a method of compensation according to the third embodiment of the disclosure.

FIG. 9 illustrates a contrast curve through a change of a control parameters SC of an array of compensation elements and a global compensation element.

FIG. 10 illustrates an example of a test pattern for a measurement of a wave-front aberration amplitude.

FIG. 11 illustrates a method of determining and calibrating a wavefront aberration amplitude in the common sensitivity units according to the fifth embodiment of the disclosure.

FIG. 12 illustrates typical contrast curves obtained by the method of determining and calibrating a wavefront aberration amplitude in the common sensitivity units.

FIG. 13 illustrates typical curves of center of gravities, obtained by the method of determining and calibrating a wavefront aberration amplitude in the common sensitivity units.

FIGS. 14A-14C illustrate an example of the rotation of coordinate systems at a setting point of a multi-beam charged particle microscope.

FIGS. 15A-15C illustrates an example of a change of rotation of coordinate systems according to a deviation from a predefined setting point.

### DETAILED DESCRIPTION

Reference will now be made in detail to exemplary embodiments, examples of which are illustrated in the accompanying drawings. Throughout the description same numbers in different drawings represent the same or similar elements unless otherwise represented. It is to be noted that the symbols used in the figures do not represent physical configurations of the illustrated components but have been chosen to symbolize their respective functionality.

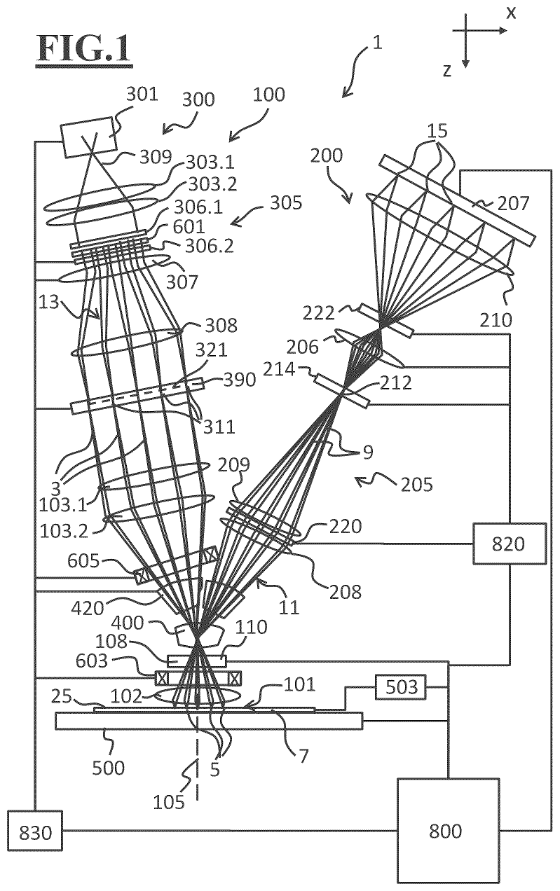

The schematic representation of FIG. 1 illustrates basic features and functions of a multi-beamlet charged-particle microscope 1 according to the first embodiment of the disclosure. The type of system shown is that of a scanning electron microscope (SEM) using a plurality of primary electron beamlets 3 for generating a plurality of primary charged particle beam spots 5 on a surface of an object 7, such as a wafer located in an object plane 101 of an objective lens 102. For simplicity, only five primary charged particle beamlets 3 and five primary charged particle beam spots 5 are illustrated.

The microscopy system 1 comprises an object irradiation unit 100 and a detection unit 200 and a beam divider unit 400 for separating the secondary charged-particle beam path 11 from the primary charged-particle beam path 13. Object irradiation unit 100 comprises a charged-particle multi-beamlet generator 300 for generating the plurality of primary charged-particle beamlets 3 and is adapted to focus the primary charged-particle beamlets 3 in the object plane 101, in which the surface 25 of a wafer 7 is placed by a sample stage 500. The sample stage 500 comprises a stage motion controller, wherein the stage motion controller comprises a plurality of motors configured to be independently controlled by control signals. The stage motion controller is connected to a control unit 800.

The primary beamlet generator 300 produces a plurality of primary charged particle beamlet spots 311 in an intermediate image plane 321, which is typically a spherically curved surface to compensate a field curvature of the object irradiation unit 100. The primary beamlet generator 300 comprises a source 301 of primary charged particles, for example electrons. The primary charged particle source 301, for example, emits a diverging primary charged particle beam 309, which is collimated by collimating lenses 303.1 and 303.2 to form a collimated beam. The collimating lenses 303.1 and 303.2 are usually consisting of one or more electrostatic or magnetic lenses, or by a combination of electrostatic and magnetic lenses. The collimated primary charged particle beam is incident on the primary multi-beamlet-forming unit 305. The multi-beamlet forming unit 305 basically comprises a first multi-aperture plate 306.1 illuminated by the primary charged particle beam 309. The first multi-aperture plate 306.1 comprises a plurality of apertures in a raster configuration for generation of the plurality of primary charged particle beamlets 3, which are generated by transmission of the collimated primary charged particle beam 309 through the plurality of apertures. The multi-beamlet forming unit 305 comprises at least a further multi-aperture plates 306.2 located, with respect to the direction of movement of the electrons in beam 309, downstream of the first multi-aperture plate 306.1. For example, a second multi-aperture plate 306.2 has the function of a micro lens array and can be set to a defined potential so that a focus position of the plurality of primary beamlets 3 in intermediate image plane 321 is adjusted. The multi-beamlet forming unit 305 further comprises an array element of compensators 601, comprising individual electrostatic elements for each of the plurality of apertures to influence each of the plurality of beamlets 3 individually. The array element of compensators 601 consists of one or more multi-aperture plates with electrostatic elements such as multi-pole electrodes or sequences of multipole electrodes to form stigmator arrays, configured to individually compensate a wave-front aberration of each of the primary charged particle beamlets. The multi-beamlet forming unit 305 is configured with a first immersion field lens 307, forming an immersion field in the plurality of apertures of the exiting multi-aperture plate, which is in this example the second multi-aperture plate 306.2 of multi-beamlet forming unit 305. With the first, immersion field lens 307, a second field lens 308 and the second multi-aperture plate 306.2, the plurality of primary charged particle beamlets 3 is focused in or in proximity of the intermediate image plane 321.

In or in proximity of the intermediate image plane 321, a beam steering multi aperture plate 390 is arranged with a plurality of apertures with electrostatic deflectors, capable to deflect individually each of the plurality of charged particle beamlets 3. The apertures of the beam steering multi aperture plate 390 are configured with larger diameter to allow the passage of the plurality of primary charged particle beamlets 3 even in case the focus spots of the primary charged particle beamlets 3 deviate from their design position. Primary charged-particle source 301 and active multi-aperture plate arrangement 306.1 . . . 306.3 and beam steering multi aperture plate 390 are controlled by primary beamlet control module 830, which is connected to control unit 800.

The plurality of focus points of primary charged particle beamlets 3 passing the intermediate image plane 321 is imaged by field lenses 103.1 and 103.2 and objective lens 102 in the image plane 101, in which surface of the wafer 7 is positioned by the sample stage 500. The object irradiation system 100 comprises a deflection system 110 in proximity to a first beam cross over 108 by which the plurality of charged-particle beamlets 3 can be deflected in a direction perpendicular to the direction of beam propagation direction (here the z-direction). Deflection system 110 is connected to control unit 800. Objective lens 102 and deflection system 110 are centered at an optical axis 105 of the multi-beamlet charged-particle microscopy system 1, which is perpendicular to wafer surface 25. The wafer surface 25 arranged in the image plane 101 is then raster scanned with deflection system 110. Thereby the plurality of primary charged particle beamlets 3, forming the plurality of beam spots 5 arranged in the raster configuration, is scanned synchronously over the surface 25. In an example, the raster configuration of the focus spots 5 of the plurality of primary charged particle 3 is a hexagonal raster of about hundred or more primary charged particle beamlets 3. The primary beam spots 5 have a distance about 6 μm to 15 μm and a diameter of below 5 nm, for example 3 nm, 2 nm or even below. In an example, the beam spot size is about 1.5 nm, and the distance between two adjacent beam spots is 8 μm. The object irradiation unit 100 according to a first example of the first embodiment of the disclosure further comprises a global compensation element 603 in proximity to the deflection scanner 110. The global compensation element 603 can be configured as a magnetic element having six, eight or more individually addressable poles to generate a magnetic field for compensating or influencing a wave-front aberration of the plurality of primary charged particle beamlets. The global compensation element 603 can be configured by a single element or by at least two multi-pole elements arranged in sequence. The global compensation element 603 is controlled by the primary beamlet control module according to a method of the disclosure describe below. In a second example of the first embodiment, the object irradiation unit 100 comprises a variation element 605 configured for varying a wave-front aberration of at least a subset of the plurality of primary charged particle beamlets 3.

The variation element 605 is not limited to an additional variation element 605, as illustrated in FIG. 1, but can for example be realized by the magnetic correction element 420, the deflection unit 110, or the global compensation element 603. In the example of FIG. 605, the variation element 605 is arranged in proximity to the magnetic correction element 420, but other positions are possible as well, for example in proximity to the beam deflection unit 110, inside of the pole elements of the magnetic objective lens 102, or in proximity of the global compensation element 603.

At each scan position of each of the plurality of primary beam spots 5, a plurality of secondary electrons is generated, respectively, forming the plurality of secondary electron beamlets 9 in the same raster configuration as the primary beam spots 5. The plurality or intensity of secondary charged particles generated at each beam spot 5 depends on the intensity of the impinging primary charged particle beamlet 3, illuminating the corresponding spot 5, the material composition and topography of the object under the beam spot. Secondary charged particle beamlets 9 are accelerated by an electrostatic field generated by a sample charging unit 503, and collected by objective lens 102, directed by beam divider 400 to the detection unit 200. Detection unit 200 images the secondary electron beamlets 9 onto the image sensor 207 to form there a plurality of secondary charged particle image spots 15. The detector comprises a plurality of detector pixels or individual detectors. For each of the plurality of secondary charged particle beam spots 20) 15, the intensity is detected separately, and the material composition of the wafer surface is detected with high resolution for a large image patch with high throughput. For example, with a raster of 10×10 beamlets with 8 μm pitch, an image patch of approximately 88 μm×88 μm is generated with one image scan with deflection system 110, with an image resolution of for example 2 nm. The image patch is sampled with half of the beam spot size of for example 2 nm, thus with a pixel number of 8000 pixels per image line for each beamlet, such that the image patch generated by 100 beamlets comprises 6.4 gigapixel. The image data is collected by control unit 800. Details of the image data collection and processing, using for example parallel processing, are described in German patent application 102019000470.1 and in U.S. Pat. No. 9,536,702 B2, which are hereby incorporated by reference.

The plurality of secondary electron beamlets 9 passes the first deflection system 110 and is scanning deflected by the first scanning system 110 and guided by beam divider unit 400 to follow the secondary beam path 11 of the detection unit 200. The plurality of secondary electron beamlets 9 are travelling in opposite direction from the primary charged particle beamlets 3, and the beam divider unit 400 is configured to separate the secondary beam path 11 from the primary beam path 13 usually via magnetic fields or a combination of magnetic and electrostatic fields. A magnetic correction element 420 are present in the primary beam path 13, and optionally also the secondary beam path 11. Projection system 205 of the detection unit 200 further comprises at least a second deflection system 222, which is connected to projection system control unit 820. Control unit 800 is configured to compensate a residual difference in position of the plurality of focus points 15 of the plurality of secondary electron beamlets 9, such that the positions of the plurality of focused secondary electron spots 15 are kept constant at image sensor 207.

The projection system 205 of detection unit 200 comprises at least a second cross over 212 of the plurality of secondary electron beamlets 9, in which an aperture 214 is located. In an example, the aperture 214 further comprises a detector (not shown), which is connected to projection system control unit 820. Projection system control unit 820 is further connected to at least one electrostatic lens 206 of projection system 205, which comprises further electrostatic or magnetic lenses 208, 209, 210. The projection system 205 further comprises at least a first multi-aperture corrector 220, with apertures and electrodes for individual influencing each of the plurality of secondary electron beamlets 9, which is connected to projection system control unit 820.

The image sensor 207 is configured by an array of sensing areas in a pattern compatible to the raster arrangement of the secondary electron beamlets 9 focused by the projecting lens 205 onto the image sensor 207. This enables a detection of each individual secondary electron beamlet 9 independent of the other secondary electron beamlets 9, which are incident on the image sensor 207. A plurality of electrical signals is created and converted in digital image data and processed to control unit 800. During an image scan, the control unit 800 is configured to trigger the image sensor 207 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

The image sensor 207 illustrated in FIG. 1 can be an electron sensitive detector array such as a CMOS or a CCD sensor. Such an electron sensitive detector array can comprise an electron to photon conversion unit, such as a scintillator element or an array of scintillator elements. In another embodiment, the image sensor 207 can be configured as electron to photon conversion unit or scintillator plate arranged in the focal plane of the plurality of secondary electron particle image spots 15. In this embodiment, the image sensor 207 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702 B2, which is incorporated here by reference. In an example, the relay optical system further comprises a beam-splitter for splitting and guiding the light to a first, slow light detector and a second, fast light detector. The second, fast light detector is configured for example by an array of photodiodes, such as avalanche photodiodes, which are fast enough to resolve the image signal of the plurality of secondary electron beamlets according to the scanning speed of the plurality of primary charged particle beamlets. The first, slow light detector can be a CMOS or CCD sensor, providing a high-resolution sensor data signal for monitoring the focus spots 15 or the plurality of secondary electron beamlets 9 and for control of the operation of the multi-beam charged particle microscope as described below in more detail.

During an acquisition of an image patch by scanning the plurality of primary charged particle beamlets 3, the stage 500 is optionally not moved, and after the acquisition of an image patch, the stage 500 is moved to the next image patch to be acquired. Stage movement and stage position is monitored and controlled by sensors known in the art, such as Laser interferometers, grating interferometers, confocal micro lens arrays, or similar. For example, a position sensing system determines the lateral and vertical displacement and rotation of the stage using any of a laser interferometer, a capacitive sensor, a confocal sensor array, a grating interferometer, or a combination thereof.

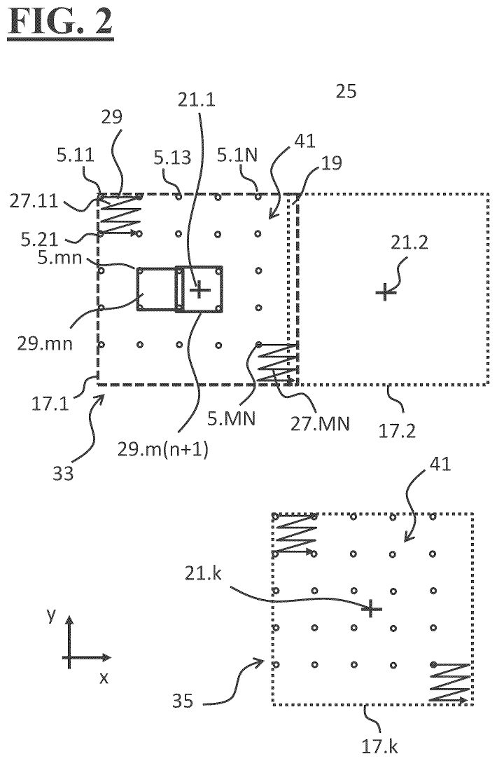

An embodiment of the method of wafer inspection by acquisition of image patches is explained in more detail in FIG. 2. The wafer is placed with its wafer surface 25 in the focus plane of the plurality of primary charged particle beamlets 3, with the center 21.1 of a first image patch 17.1. The predefined position of the image patches 17.1 . . . k corresponds to inspection sites of the wafer for inspection of semiconductor features. The predefined positions of the first inspection site 33 and second inspection site 35 are loaded from an inspection file in a standard file format. The predefined first inspection site 33 is divided into several image patches, for example a first image patch 17.1 and a second image patch 17.2, and the first center position 21.1 of the first image patch 17.1 is aligned under the optical axis of the multi-beam charged-particle microscopy system for the first image acquisition step of the inspection task. Methods to align the wafer, such that the wafer surface 25 is registered and a coordinate system of wafer coordinates is generated, are well known in the art.

The plurality of primary beamlets is distributed in a regular raster configuration 41 in each image patch and is scanned by a scanning mechanism to generate a digital image of the image patch. In this example, the plurality of primary charged particle beamlets 3 is arranged in a rectangular raster configuration 41 with n primary beam spots 5.11, 5.12 to 5.1N in the first line with N beam spots, and M lines with beam spots 5.11 to beam spot 5.MN. Only M=five times N=five beam spots are illustrated for simplicity, but the number of beam spots M times N can be larger, and the plurality of beam spots 5.11 to 5.MN can have different raster configurations 41 such as a hexagonal or a circular raster.

Each of the primary charged particle beamlet is scanned over the wafer surface 25, as illustrated at the example of primary charged particle beamlet with beam spot 5.11 to 5.MN with scan path 27.11 to scan path 27.MN of the plurality of primary charged particle beamlets. The scanning of each of the plurality of primary charged particle beamlets 3 is performed according to a preselected scan program, for example in a back- and forth deflection by scanning deflector 110 in x-direction with a interlaced deflection by the scanning deflector 110 in y-direction. For the image acquisition, a plurality of secondary electrons is emitted at the scanning positions of the focus points 5.11 to 5.MN, and a plurality of secondary electron beamlets 9 is generated. The plurality of secondary electron beamlets 9 are collected by the objective lens 102, pass the first deflection system 110 and are guided to the detection unit 200 and detected by image sensor 207. A sequential stream of data of each of the plurality of secondary electron beamlets 9 is transformed synchronously with the scanning paths 27.11 . . . 27.MN in a plurality of 2D dataset, forming the digital image data of each image subfields 29.11 to 29.MN. The plurality of digital images of the plurality of subfields 29.11 to 29.MN is finally stitched together by an image stitching unit to form the digital image of the first image patch 17.1. The operation is repeated for a second image patch 17.2 at the first inspection site 33, and after acquisition of the image data at the first inspection site, the wafer 7 is moved to the next inspection site 35 with image patch 17.k.

Next, the desired properties or specifications of a wafer inspection task are illustrated. For a high throughput wafer inspection, the image acquisition of image patches 17.1 . . . k as well as the stage movement between image patches 17.1 . . . k is fast. On the other hand, tight specifications of image qualities such as the image resolution, image accuracy and repeatability is maintained. For example, the desired image resolution is typically 2 nm or below. For example, the edge position of features, in general the absolute position accuracy of features is to be determined with high absolute precision. Typically, the desired position accuracy is about 50% of the desired resolution or less. Image contrast and dynamic range is enough such that a precise representation of the semiconductor features and material composition of the wafer under inspection is obtained. Typically, a dynamic range is better than 6 or 8 bit, and the image contrast is better than 80%. A dominating aberration which limits the resolution and contrast of each image data of an image subfield 29.mn corresponding to a focus point 5.mn of a primary charged particle beamlet 3.mn is given by first order astigmatism. Other aberrations might be present as well, like trefoil aberrations or higher astigmatism. The primary astigmatism is formed by two components

$$AST 0 = A 0 {r}^{2} cos 2 φ$$

$$AST 45 = A 45 {r}^{2} sin 2 φ$$

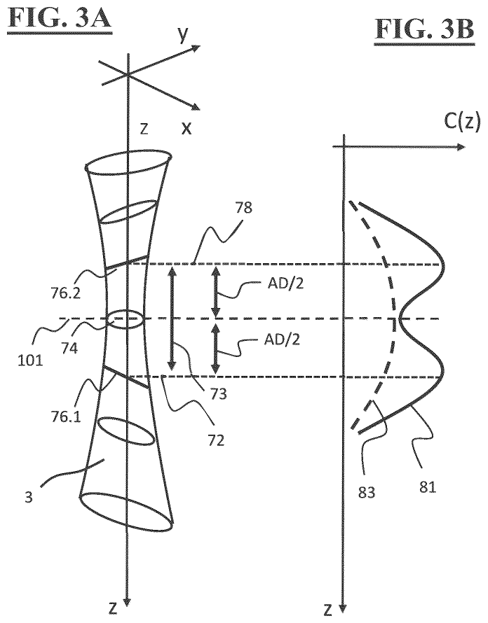

with r being the distance of the particle trajectory from a center trajectory of a beamlet and φ being the polar angle. In other word, radius r and polar angle φ describe the pupil coordinates of the charged particle trajectories in a primary beamlet. In FIG. 3, the effect of a wave-front aberration of a primary charged particle beamlet 3 is explained at the example of AST0. FIG. 3A shows a perfectly aligned beamlet 3, which is propagating along the z-axis, which is perpendicular to a wafer surface 25 (not shown). In the image plane 101, the astigmatic beamlet 3 forms a circular spot 74 of least confusion. The diameter of the circular spot 74 of least confusion depends on the amplitude of the wave-front aberration (here AST0) and increases with increasing amplitude. Therefore, an image contrast or a resolution in the image plane 101 decreases with increasing wave-front aberration amplitude. At a first line focus plane 72 with positive z-position of distance AD/2 from the image plane 101, a first line-shaped focus 76.1 is formed and at the second line focus plane 78 with negative distance AD/2, the second line-shaped focus 76.2 is formed with a relative angle of 90° to the first line shaped focus 76.1. Outside of the planes, the shape of the beamlet is elliptical. The astigmatic difference AD (reference number 73) is proportional to the amplitude A0 of the AST0.

In FIG. 3B, two exemplary contrast curves through focus of z-distance are illustrated. The first contrast curve 81 shows the contrast through focus at a typical semiconductor probe with horizontally and vertically aligned structures (HV-structures). In the two planes 73 and 78, the line foci are either parallel or perpendicular to HV-structures and the maximum image contrast of an image of a waver surface segment thus shows to maximums. In the image plane 101, the contrast curve 81 shows a local minimum, and the contrast curve at the local minimum has approximately a parabolic shape. The second contrast curve 83 shows an example of an arbitrary probe with arbitrarily oriented structures. Here the contrast curve has a maximum in the image plane 101 and contrast curve at the maximum has approximately a parabolic shape. In each case, the contrast curves show in the image plane 101 a local extremal value of the image contrast with an approximately parabolic shape around the local extremal value (either maximum or minimum).

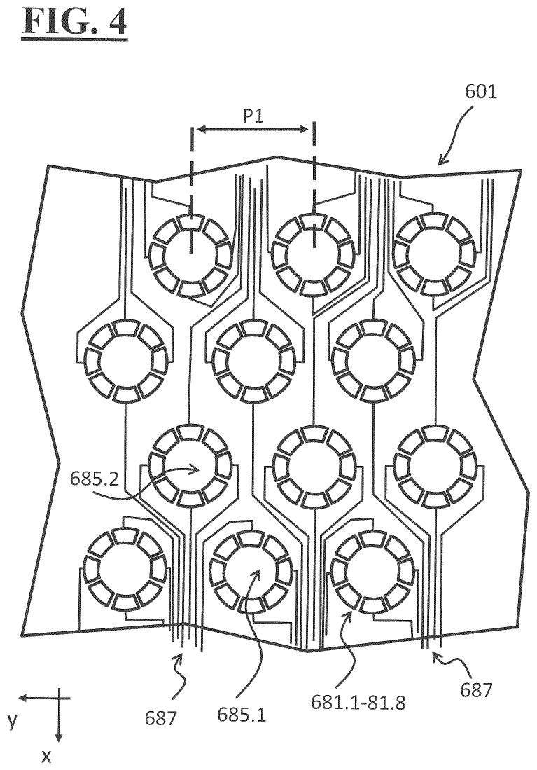

FIG. 4 illustrates the array of compensation elements 601. Such an array of compensators is well known in the art, as for example in U.S. Pat. No. 10,147,582 BB, which is incorporated herein by reference. The multi-aperture array 601 comprises a plurality of apertures arranged in the raster configuration 41 of the plurality of primary charged particle beamlets 3—in this example a hexagonal raster configuration. Two of the apertures are illustrated with reference numbers 685.1 and 685.2. In the circumference of each of the plurality of apertures, a plurality of electrodes 681.1-681.8 is arranged, in this example the number of electrodes is eight, but other numbers such as four, six or more are possible as well. The electrodes are electrically insulated with respect to each other and with respect to a carrier of the array of compensators 601. Each of the plurality of electrodes 681 is connected by one of the electrically conductive lines 607 or wiring connection (not all are shown) to a control module. By application of individual and predetermined voltages to each of the electrodes 681, different effects can be achieved for each the plurality of primary charged particle beamlets passing each of the apertures 685. In an example, a plurality of for example two or three of such multi aperture plates 601 is arranged in sequence. A method of operation of the multi-beam charged particle microscope 1 with the array of compensators 601 will be explained in the embodiments below.

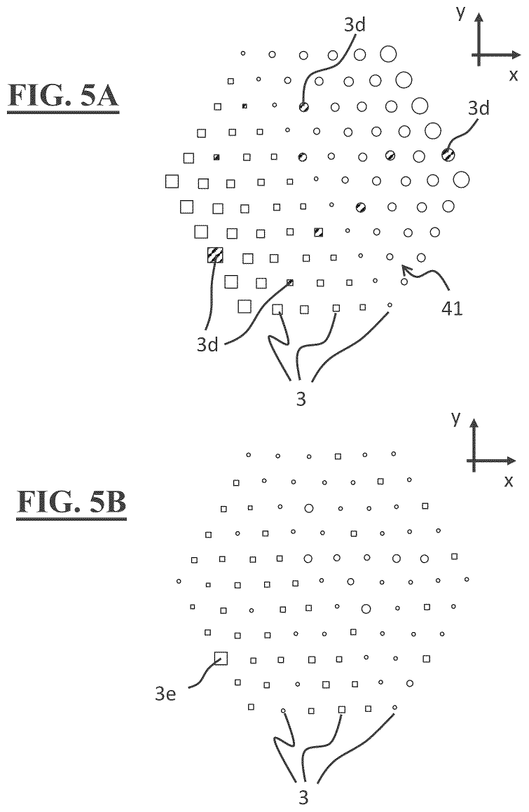

In multi-beam systems, the wave-front aberrations have typically two different contributions. The first contribution is from the combination of the global elements of the multi-beam system 1, such as the deflector 110, the objective lens 102 or the beam divider unit 400. The second contribution is from the primary multi-beamlet-forming unit 305. FIG. 5A illustrates a typical field dependency of a primary AST0 of a plurality of primary charged particle beamlets 3 in a hexagonal raster configuration 41. The circles identify a positive amplitude A0, the squares identify a negative A0 of a primary charged particle beamlet 3, and the diameter of the symbols are proportional to the amplitude A0 of the wave-front aberration AST0. The distribution of amplitudes of the wave-front aberration has a third contribution with a systematic field dependency. As visible in FIG. 5A, the amplitudes A0 of AST0 shows a dominant linear dependency over the field coordinates in x and y. In addition, the distribution of amplitudes of the wave-front aberration shows a fourth contribution, which is illustrated in FIG. 5A at some examples of the beamlets identified with numeral 3d. Here, the wave-front aberration AST0 shows a local deviation from the linear dependency. FIG. 5B illustrates the residual wave-front aberration after subtraction of the systematic field dependency (here the linear dependency in x and y) of the wave-front aberration. The diameters correspond to the residual fourth contribution of the wave-front aberration AST0 at enlarged scale compared to FIG. 5A.

According to the second embodiment of the disclosure, a method of determination of the amplitudes of the wave-front aberration of each of the primary charged particle beamlet is given. Typically, the wave-front aberration cannot be measured directly. Instead, and for general use, the plurality of J wave-front aberrations A(j=1 . . . J) is indirectly determined by a sequence of contrast measurements at different control parameters of a variation element 605. The control parameter value of maximum image contrast is derived from the sequence of measurement. The control parameter value SV(maxC(j)) at maximum or minimum image contrast corresponds to the wave-front aberration AV in units of the control parameter of the variation element 605 and is thus specific to the variation element 605. A wave-front aberration A in normalized sensitivity units is then derived for example in relative units and symbol A is used in the following for the amplitude of the wave-front error in normalized sensitivity units. As will be explained in the third embodiment below, the derivation of normalized wave-front amplitudes A(j) in 20) in normalized sensitivity units allows the determination of amplitudes of a wavefront aberration with a first or variation element 605 and the compensation of a wavefront aberration with a second or compensating element 601 or 603, which is different from the first or variation element 605. The variation element 605 can be any element which has an influence on the wave-front aberration of interest, for example the magnetic correction element 420 or the scanning deflector 110 or other components. In an alternative example, the global compensation element 603 is used as variation element 605 to change the wave-front aberration of interest. The control parameter can be either a voltage of an electrostatic element or a current of a magnetic field element. By utilizing a global variation element 605, the control parameter SV of only a single element has to be changed and the method of determining the amplitudes of a wave-front aberration A(j) can be performed with enhanced speed and a reduced complexity. In a first example, the wave-front aberration amplitudes AV are then converted into wave-front aberration amplitudes AC in units of the maximum range of a compensation element. In a second example, the wave-front aberration amplitudes AV are converted onto absolute wave-front aberration amplitudes A in normalized sensitivity units.

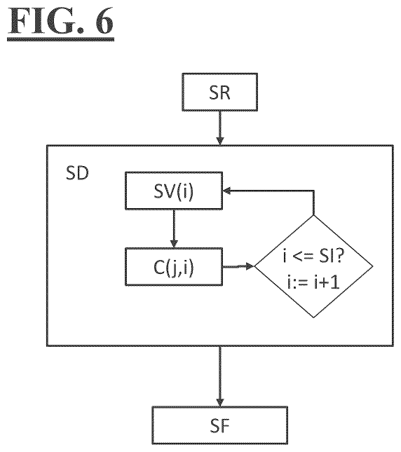

An example of the method according to the second embodiment is described in FIG. 6. The method is configured to determine the amplitudes of the wave-front aberration including the first and the second contribution. The method is applicable to an arbitrary object 7, as long the object 7 generates an image contrast. The method is described at the example of AST0, but it can be applied for any wave-front aberration such as AST45, coma, higher order astigmatism or trefoil aberrations.

In an initial step SR, the surface 25 of an object 7 is adjusted in the image plane 101 of the multi-beamlet charged-particle microscope 1. Such a method is described in German patent application 102021200799.6, filed on Jan. 29, 2021, which is hereby incorporated by reference. The initial settings of the multi-beamlet charged-particle microscope 1 are for example determined by a focus series and an optimal focal plane is determined as setting point. Next, the control unit 800 triggers the determination of AST0.

In step SD, a sequence of i=1 to i=SI contrast measurements is repeated. For each contrast measurement, a control parameter SV of a variation element 605 is changed through a sequence of control parameters SV(i=1 to SI). The number SI of contrast measurements is typically selected with SI>=3, such as greater or equal to 5. The image contrast C(j,i) for each of the plurality of J charged particle beamlets is determined at the features present at the object surface 25 for each control parameter SV(i) of the variation element. The plurality of image contrast values C(j=1 . . . J, I=1 . . . SI) are temporarily stored in a memory.

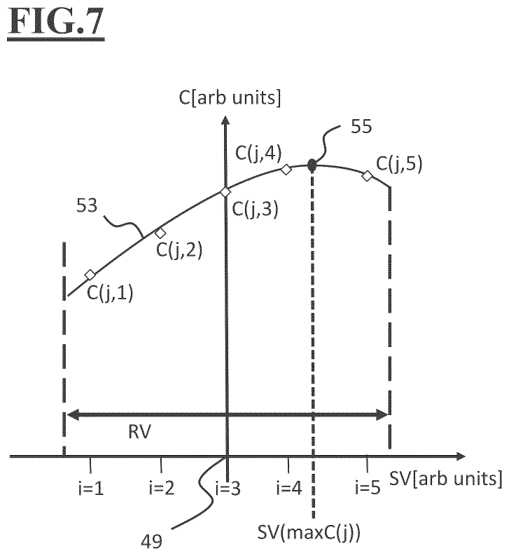

In step SF, the contrast curves C(j,i) for each of the plurality of J primary charged particle beamlets are analyzed and an optimal control parameter SV(maxC(j)) for the maximum contrast value maxC(j) is numerically determined for each beamlet j. The determination can be performed for example by a polynomial fit, for example by fitting a parabola to the measurement points. An example is illustrated in FIG. 7. For a primary charge particle beamlet j, the image contrast is measured at five different control parameter values SV(i=1) to SV(i=5). The measurement value for i=3 corresponds to the setting point 49, where the control parameter value SV(3) of this example is set to zero (SV(3)=0). However, this is not always be the case. According to the determination of the setting point during step SR, a control parameter value of a variation element 605 can have an offset control parameter value deviating from zero.

A parabolic fit C(j; i), identified with reference number 53, is approximated to the measurement points C(j, i=1) to C(j, i=5) and a maximum max(C(j)) (see reference number 55) is determined. The optimal control parameter value SV(maxC(j)) corresponding to the maximum contrast value 55 is determined. The maximum contrast value max(C(j)) can be different for each of the plurality of J primary charged particle beamlets, for example due to other wave-front aberrations or specific other defects of this beamlet. Further, the parabolic shape of each contrast curve C(j) can be different for each beamlet with j=1 . . . J, depending on the sensitivity of the wave-front aberration of this beamlet to a parameter variation of the variation element.

In a first example, the wave-front amplitudes A(j) in normalized sensitivity units are determined for each of the plurality of primary beamlets 3 in relation to a predetermined control parameter range RV of the variation element with A(j)=SV(maxC(j))/RV. The determination is repeated or performed in parallel for each beamlet. The control parameter range RV of the variation element 605 is for example determined in a previous calibration step and adjusted such that a same range of wave-front aberration amplitudes can be achieved with the control parameter range RV or the variation element 605 as with the control parameter range of a global compensation element 603 or each element of the array of compensation element 601. The corresponding ranges or the variation and compensation elements are then adjusted, and it is possible to control a compensator element with the determined wave-front amplitude A in normalized sensitivity units.

In a second, equivalent example, the wave-front amplitudes A(j) in normalized sensitivity units are derived from the curvature of the contrast curves 53. The parameters of the parabolic fit are extracted for each of the J contrast curves with the parabolic coefficient KV describing the parabolic part:

C(j;SV)=maxC(j)−KV(j)(SV−SV(maxC(j)))²

The wave-front aberration amplitudes A(j) in normalized sensitivity units at the setting point 49 in the image plane 101 are then determined according to the derivation of the parabolic contrast curve at SV=0:

$$A ( j ) = SIGN ( j ) * 2 KV ( j ) * SV ( max C ( j ) ) .$$

The sign(j) of the absolute amplitude is determined in accordance with the definition of the coordinate systems. In the second example, the parabolic coefficient KV(j) describes the sensitivity of the wavefront aberration with respect to a variation of the control parameter and is thus also called the parabolic sensitivity parameter. A result of the determination of the absolute wave-front amplitudes A(j) in normalized sensitivity units is illustrated in FIG. 5A.

For a higher precision, a higher order approximation or fit to the measured contrast values can be performed, for example a hyperbolic fit or a higher order polynomial fit. The wave-front aberration amplitude in normalized sensitivity units is derived from the approximated fit curve to the contrast values at SV=0.

For the determination method it is not necessary to acquire digital images from entire images subfield as illustrated in FIG. 2. The contrast measurement for each beamlet can also be performed at smaller image subfields with a lower number of scanning positions and scanning lines, for example 128×128 pixel or 256×256 pixel. For objects with similar surface structure as for example structured semiconductor wafers, it is also possible to perform the contrast measurement at different, smaller image subfields within the scan range of the deflection scanner 110. Thereby, charging effects on the contrast measurements for different parameters of the variation element are minimized. In an example, the determination method is not applied to every beamlet of the plurality of J beamlets.

A method of determining a plurality of wave-front aberration amplitudes A(j) is therefore comprising the steps of (a) setting the multi-beam microscope (1) to a setting point of an inspection task; (b) varying a wave-front aberration of a plurality of J primary charged particle beamlets (3); (c) determining a plurality contrast curves C(j=1 . . . J) from a plurality of contrast values C(j,i) for each of the plurality of J primary charged particle beamlets (3); and (d) determining a plurality of J wave-front aberration amplitudes in normalized sensitivity units A(j=1 . . . J) at the setting point from the plurality of contrast curves C(j=1 . . . J). The wave-front aberration is varied by providing a series of at least SI=3 different variation control signal SV(i=1 . . . SI) to a variation element (605) and measuring the plurality of contrast values C(j,i) at each variation control signal SV(i=1 . . . SI) for each of the plurality of J primary charged particle beamlets (3). Each contrast curve C(j) can be obtained by a parabolic, hyperbolic or polynomial approximation to the i=1 . . . SI contrast values C(j,i) for each of the plurality of J primary charged particle beamlets (3). In a first example, the wave-front amplitudes A(j) in normalized sensitivity units are determined from the variation control signal SV(maxC(j)) at a maximum contrast value maxC(j) divided by a normalized range RV of the variation element 605. The normalized range RV can be determined from the difference of a maximum and a minimum control signal SV used to achieve a predetermined variation of the image contrast of at least one beamlet of the plurality of primary charged particle beamlets. In a second example, the wave-front amplitudes A(j) in normalized sensitivity units are determined from a parabolic coefficient KV(j) of the contrast curve C(j).

During use, the setting point can deviate from a design setting point and due to a rotation of the primary charged particle beamlets in magnetic fields, the setting point can comprise a deviation of a predetermined rotation of the raster configuration (41) of the plurality of primary charged particle beamlets (1) between the coordinate systems of the image plane (101), the array of compensator components (601), the global compensation element (603) and/or the variation element (605). In an example of the method according to the second embodiment, the wave-front aberration amplitudes are transformed into a wave-front aberration amplitude vector, for example vector [AST0, AST45]. The deviation of a predetermined rotation of the raster configuration (41) of the plurality of primary charged particle beamlets (1) between a coordinate system of an image plane (101), an array of compensator components (601), a global compensation element (603) and/or the variation element (605) can be considered by multiplication of the wave-front aberration amplitude vector [AST0, AST45] with a rotation matrix M.

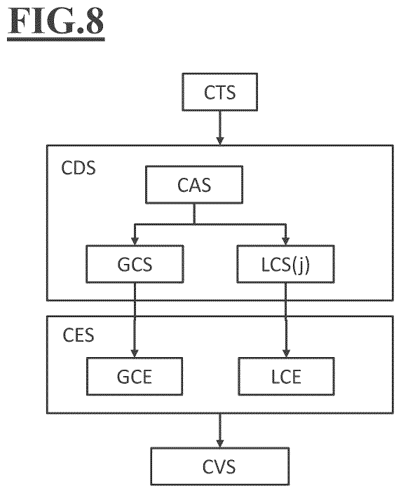

After the wave-front aberration amplitudes A(j), which are present in the multi-beam charged particle system 1, are determined according for example the method of the second embodiment, the wave-front aberration amplitudes A(j) can be minimized by at least a compensator element. According to the third embodiment of the disclosure, a method of compensating the wave-front aberration amplitudes A(j) of the plurality of J primary charged particle beamlets is described. An example of the method of compensating the wave-front aberration amplitudes A(j) in a multi-beam charged particle microscope 1 is described in FIG. 8.

In a first compensation triggering step CTS, the wave-front aberration amplitudes A(j) of the plurality of J primary charged particle beamlets 3 of a multi-beam charged particle microscope 1 are received and analyzed. Whenever a wave-front aberration amplitude A(j) of a primary charged particle exceeds a predetermined maximum threshold of the wave-front aberration amplitude, a compensation is triggered by the subsequent steps of the method.

The wave-front aberration amplitudes A(j) can for example be received from the method of determination of the wave-front aberration amplitudes A(j) according of the first embodiment. Other inputs can be received from other measurement results, or from a monitoring and a model-based control. Model-based control predict a primary expected behavior, for example a change of a wave-front aberration amplitude, based on predetermined model assumption and secondary, indirect monitoring parameters like up-time of the multi-beam charged particle microscope or temperature of components. Model-based control algorithms are further disclosed in PCT/EP2021/061216, filed on May 28, 2020, which is incorporated herein by reference. In an example, a determination of wave-front aberration amplitudes A(j) at the setting point 49 is triggered by a monitoring method. In an example, during use of a monitoring method, changes of the image contrast of the digital images generated during an inspection or metrology task is monitored. When an image contrast varies and is for example below a predetermined threshold of a minimum contrast for at least one of the plurality of primary charged particle beamlets, a wavefront aberration measurement is triggered. A monitoring method is described in the fourth embodiment in more detail.

In the compensation determination step CDS, the amplitudes A(j) are analyzed. In the compensation analysis step CAS, at least a first component of amplitude AG1 with a field dependency of at least a first global compensation element is determined by a best fit of the field dependency to the amplitudes A(j). Typically, a global compensation element shows low order field dependency on a wave-front aberration, such as a constant field dependency, a linear field dependency, or a field dependency of second order. In an example, the field dependency of a wave-front aberration is expanded in a so-called double-Zernike expansion, with wave-front aberrations as well as field dependency expanded in Zernike polynomials. For the normalized computation of the amplitude AG1 of the field dependency, the maximum field radius is set to 1.

The global compensation element can be the global compensation element 603, the deflection scanner 110, the magnetic field component 420, or any other electron-optical element in the primary beam path, which has a significant impact on the wave-front aberration of interest, but a low impact on other properties of the multi-beam charged particle microscope 1. It is also possible to use several global compensation elements, for example the first global compensation element 603 and the deflection scanner 110 as second global compensation element. The deflection scanner 110 is for example realized as an electrostatic or magnetic octupole element, and a compensation signal to compensate a wave-front aberration can be provided as an offset signal to some of the eight poles. Thereby, for example an almost constant offset of an astigmatism can be compensated. In an alternative example, an element comprising six or multiples of six poles can be provided, capable of compensating a trefoil aberration.

The first component AG1, which can be compensated by the at least one global compensation element is subtracted from the amplitudes A(j) and a residual, second component of residual wave-front amplitudes Ares(j) is obtained. This second component Ares(j) cannot be corrected with global compensation elements.

From the first component AG1, a global correction signal GCS is derived for the at least one global compensation element. The global correction signal GCS is derived from the amplitude AG1 of the field dependency and from a predetermined sensitivity of the global compensation element.

As a result of a determination of the predetermined sensitivity of the global compensation element, a similar contrast curve as shown in FIG. 7 is obtained for at least a representative beamlet and a variation of the control signal of the global compensation element, however with a difference in scaling. The contrast through variation of the compensator shows again a parabolic shape with a parabolic sensitivity parameter KC. The predetermined parabolic parameter KC is stored in a memory of the control unit 800. More details of the determination of the calibration parameters are explained in the fifth embodiment of the disclosure.

The global correction signal GCS is obtained by

$$GCS = SIGN * AG 1 / ( 2 * KC ) .$$

From the second component, a plurality of J local compensation signals LCS(j) are computed for each of the J primary charged particle beamlets. For each of the compensator elements of the array element 601, a plurality of predetermined individual parabolic parameters KLC(j) is used to compute the plurality of local compensation signals LCS(j) by

$$LCS ( j ) = SIGN ( j ) * Ares ( j ) / ( 2 * KLC ( j ) ) .$$

The signs are predetermined according to the definition of the coordinate systems and are for example defined in consistence with the definition of the signs during a determination step of the wave-front amplitudes.

In an example, the compensation determination step CDS is performed by the control unit 800. The control unit 800 therefore comprises a memory to save the field dependency of global compensator element 603 and the predetermined parabolic sensitivity parameter KC of the global compensator element 603. In the memory, further the plurality of j=1 . . . J predetermined parabolic sensitivity parameter KLC(j) are stored. In another example, the predetermined parabolic sensitivity parameter KC of the global compensator element is stored in an operation control unit of the global compensator element, and the conversion in global correction signal GCS is performed in the operation control unit of the global compensator element. Similarly, the computation of the plurality local compensation signals LCS(j) can be performed in an operation control unit of the array of global compensation element 601.

The compensation determination step CDS is performed with wavefront aberration amplitudes A(j) in normalized sensitivity units, here described at the example of parabolic sensitivity parameters KV, KC and KLC(j). Other examples of scaling of the wavefront amplitudes from for example a variation element 605 to two compensation element 603 and 601 are possible as well. An example is utilizing the scaling of wavefront amplitudes with the different maximum parameter ranges of compensation element 601 and 605, in analogy to the scaling of A(j)=SV(maxC(j))/RV in normalized sensitivity units of the variation element as described above in the first example of the second embodiment.

In the compensation execution step CES, the global compensation signal GCS is provided to the global compensation element, for example element 603, and a global compensation of the first component of the wave-front aberration is achieved in step GCE. The plurality of local compensation signals LCS(j) is provided to the array of compensation elements 601 and a local compensation of the residual wave-front aberration is achieved in step LCE.

In an optional verification step CVS, the compensated wave-front aberration is measured again, for example with the method described in the first embodiment. To achieve an even better compensation of the wave-front aberration, the method steps CDS, CES and CVS can also be iteratively repeated until the compensated wave-front aberration is below a predetermined threshold.

A method according to the third embodiment of compensating a plurality of wave-front aberrations of a multi-beam charged particle microscope (1) at a setting point is therefore comprising the steps of (a) receiving a plurality of J wave-front aberration amplitudes A(j=1 . . . J) of a plurality of J primary charged particle beamlets (3) in normalized sensitivity units; (b) determining a global component of amplitude AG1 in normalized sensitivity units, the global component having a predetermined field dependency of the plurality of J wave-front aberration amplitudes A(j) of a global compensation element (603); (c) determining a residual component of a plurality of residual wave-front amplitudes Ares(j) in normalized sensitivity units; (d) transforming the global component in a global correction signal GCS; (e) transforming the residual component in a plurality of local compensation signals LCS(j); (f) providing the global correction signal GCS to a global compensating element (603); and (g) providing the plurality of local compensation signals LCS(j) to an array of compensation elements (601). The first step (a) can comprise the method of determining the plurality of J wave-front aberration amplitudes A(j) according to the second embodiment. According to the method of third embodiment, the wave front aberration amplitudes A(j) are transformed in normalized sensitivity units, and the sensitivity of a compensation element is described in the same normalized sensitivity units. In a first example, the normalized range RC of a global compensation element (603) and the normalized range RL of the array of compensation elements (601) is previously determined and stored in a memory of the control unit (809). In the first example, the wave-front aberration amplitudes as well as the control signals for the compensator elements are normalized with the normalized ranges RV, RC and RL. In the second example, the parabolic sensitivity constants KV, KC or KLC(j) are used instead and a consistent scaling of the wave-front aberration amplitudes and control signals to drive the compensators is achieved.

The determination of the wave-front amplitudes A(j) according to the method of the second embodiment is a fast and reliable method of determining a wave-front aberration. The method can be applied to any object which produces some image contrast. Especially, it is not required to change the inspection site of an object with a dedicated metrology object. The method is further applicable for a monitoring of a wave-front aberration throughout an inspection or metrology task. According to a fourth embodiment of the disclosure, a monitoring of a multi-beam charged particle microscope 1 is performed by regular application of the determination method according to the second embodiment. In an example, the monitoring is performed by extracting the contrast parameters of the images obtained from image subfields at different, consecutive inspection sites. Typically, during a wafer inspection, the average image contrast at different inspection sites should not vary. If a contrast variation exhibits a specific field dependency of a wave-front aberration such as for example the linear field dependency in x any of AST0 as illustrated in FIG. 5A, a determination step of the wave-front amplitudes according to the second embodiment is triggered, followed by a compensation method according to the third embodiment. In the fourth embodiment, the control unit 800 is configured to monitor a contrast variation of the plurality of charged particle beamlets during a wafer inspection task. The control unit 800 is further configured to analyze the contrast variation and determine at least a first field dependency of a first wave-front aberration, for example AST0 or AST45. If the at least first field dependency is detected by the control unit 800, the wave-front amplitudes of the corresponding wave-front aberration AST45 are determined. The control unit 800 is further configured to determine further field dependencies, for example a second field dependency of a second wave-front aberration, for example AST0. If the second field dependency is detected by the control unit 800, the wave-front amplitudes of the corresponding wave-front aberration AST0 are determined.

In a further example of the method of monitoring of a multi-beam charged particle microscope 1 according to the fourth embodiment, the throughput is further increased by monitoring only selected primary charged particle beamlets. From the plurality of primary charged particle beamlets 3, only a small number of two or more beamlets is selected, which are representative for a low order field dependency of a wave-front aberration. In an example, at least two selected beamlets with a large spatial distance to each other are used to monitor a linear field dependency of the wave-front aberration of interest, such as for example AST0 or AST 45. In an example of the monitoring method, the wave-front aberrations of three selected beamlets with large distance to each other is changed using the corresponding compensators of the array of compensation elements 601, while leaving the plurality of other primary beamlets unchanged. The control unit triggers during the monitoring a change of the wavefront aberration of only these three selected beamlets. From a change in image contrast generated by the selected beamlets, the amplitudes of the wave-front aberration of the selected beamlets are determined and a first component or the low-order field dependency of the wave-front aberration is determined. The first component or linear field dependency of the wave-front aberration is then compensated by the appropriate global compensator 603 with the linear field dependency of the wave-front aberration. The residual wave-front error amplitudes Ares are compared to a threshold. If an Ares exceeds a threshold, the full determination and compensation according to the second and third embodiment of the disclosure is triggered. According to the third example, a wave-front aberration of any selected beamlet can be varied with the corresponding compensator of the array of compensation elements 601. During the monitoring, a wave-front aberration of different selected beamlets can be changed, such that different low order field dependencies of for example AST0, AST45, coma or trefoil aberrations can be determined.

According to a further example, a model-based control based on a predetermined model of the multi-beam charged particle microscope (1) and secondary, indirect monitoring parameters is utilized in the monitoring method. According to the model-based control, an image contrast of a plurality of digital images received during an inspection task is predicted according to the predetermined model and a wave-front determination and/or compensation step is triggered when a predicted image contrast is below a predetermined threshold.

A desired property or specification of a wafer inspection task is throughput. The throughput depends on several parameters, for example the measured area per acquisition time itself. The measured area per acquisition time is determined by the dwell time, resolution and the number of beamlets. Typical examples of dwell times are between 20 ns and 80 ns. The pixel rate at the fast image sensor 207 is therefore in a range between 12 Mhz and 50 MHz and each minute, about 20 image patches or frames could be obtained. Between the acquisition of two image patches, the wafer is laterally moved to the next point of interest by the wafer stage. For 100 beamlets, typical examples of throughput in a high-resolution mode with a pixel size of 0.5 nm is about 0.045 sqmm/min (square-millimeter per minute), and with larger number of beamlets and lower resolution, for example 10000 beamlets and 25 ns dwell time, a throughput of more than 7 sqmm/min is possible. The stage movement including acceleration and deceleration of the stage is one of the limiting factors for the throughput of the multi-beam inspection system. A faster acceleration and deceleration of the stage in short time typically involve a complex and expensive stage or induces dynamical vibrations in the multi-beam charged particle system. Since no additional stage movement is used, the second to fourth embodiments of the disclosure enable a determination and compensation of wave-front aberrations such as astigmatism with high throughput of a wafer inspection task and maintain the image performance specification well within the desired resolution and repeatability. The monitoring according to the third example at for example only three beamlets allows the performance of the monitoring in parallel to a wafer or mask inspection, in which the plurality of primary beamlets with exception of the few selected beamlets for monitoring is used for wafer or mask inspection.

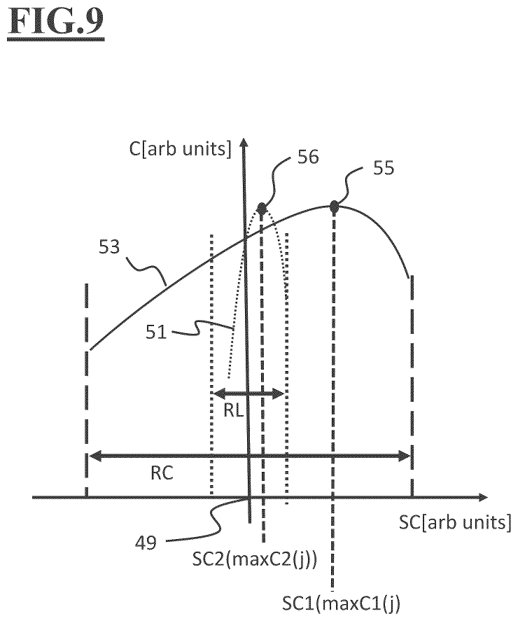

In a fifth embodiment, a method of determining the parabolic sensitivity parameter KC and KLC(j) is illustrated. In a first example, the parabolic sensitivity parameter KC and KLC(j) are determined in a method similar to the determination method according to the second embodiment. However, in difference to the determination method according to the second embodiment, the parabolic sensitivity parameter KC or KLC(j) are determined by variation of a compensation element 601 or 603 and by obtaining contrast curves through variation of a corresponding element. FIG. 9 illustrates the contrast curves at two different examples for the same beamlet j. The contrast curve 53 of a representative beamlet of a global compensation element 603 is obtained by varying a control parameter SC of the global compensation element 603 with for example SI=5 different control parameter values SC(SI=1 . . . I). A parabolic fit to the I obtained contrast values C1(i=1 . . . I) is performed. A maximum contrast value 55 and the corresponding control parameter value of the maximum contrast position SC(maxC1(j) is determined. The range RC of the global compensation element 603 is for example adjusted to compensate the same range of a wave-front aberration as the range RV of variation of the wave-front aberration amplitude by variation element 605. The parabolic constant KC is determined and stored in the memory of the control unit 800. The representative beamlet is selected according to a field dependency of the global compensation element 603. A similar operation is performed for the compensator of the array element 601 for each beamlet j=1 . . . J. Second contrast values C2(i=1 . . . SI) are determined by variation of the control parameter of the compensator of the array element 601 for each beamlet j and the parabolic sensitivity coefficients KLC(j) are determined. FIG. 9 illustrates on contrast curve 51 with maximum value maxC2 (with index 56). Typically, a compensator of an array of compensators 601 has a larger impact or sensitivity to a wave-front aberration and is driven over a smaller range RL. The method is repeated for each of the J beamlets j=1 . . . J. The parabolic constants KLC(j) are typically slightly different and larger compared to the parabolic constant KC of a global compensator. The determination of the parabolic constants KC and KLC(j) is also possible when a wave-front aberration is present. The situation in FIG. 9 illustrates a situation when a wave-front aberration is present, since the maximum contrast maxC1 and maxC2 are at a parameter value SC deviating from zero. The method of calibration according to the first example of the fifth embodiment can be performed at a wafer surface with structures generating an image contrast. The method of calibration according to the first example can therefore be performed during a wafer inspection task, for example when a method of compensation of a wave-front error according to the third embodiment does not converge even after several iterations. In an example, individual compensators of the array of compensator 601 can be subject to drifts or contamination, which makes a re-calibration of the compensator necessary. In such cases, the method of calibration according to the first example can also be performed only for the individual compensator of the array of compensators 601 which exhibits a deviating behavior during the method of compensation.

The first example of the calibration method of a charged particle optical element, such as a global compensator (603) or a compensator element of an array of compensator elements (601), or a variation element (605), comprises the steps of: (a) varying the wave 20) front aberration of a plurality of J primary charged particle beamlets (3) by providing a series of at least SI=3 different control signal SC(i=1 . . . SI) to the charged particle optical element; (b) measuring a plurality of contrast values C(j=1 . . . J, i=1 . . . SI) at each different control signal SC(i=1 . . . SI) for each of the plurality of J primary charged particle beamlets (3); (c) determining a plurality contrast curves C(j=1 . . . J,SC) from the plurality of contrast values C(j,i) for each of the plurality of J primary charged particle beamlets (3); (c) determining an extremal value maxC(j) and the control signal SC(maxC(j)) corresponding to the extremal value maxC(j) of each of the contrast curves C(j,SC); and (f) determining a plurality of variations of the wave-front amplitudes A(j) effected by the charged particle optical element in normalized sensitivity units. The normalized sensitivity units of a first example are given by A(j)=SC(maxC(j))/RC, with RC being a normalized range of the charged particle optical element, corresponding to the difference between a maximum and a minimum control signal SC used to achieve a predetermined variation of the image contrast C(j) for at least one of the plurality of J primary charged particle beamlets. The normalized sensitivity units according to the second example are given by A(j)=SIGN(j)*2 KV(j)*SC(maxC(j)), with the parabolic constant KC(j) of an approximation to a contrast curve C(j=1 . . . J,SC) in proximity of the extremal value max(C(j,SC)). The plurality of variations of the wave-front amplitudes A(j) of the charged particle optical element in normalized sensitivity units are stored in a memory of a control unit (800) of the multi-beam charged particle microscope (1).

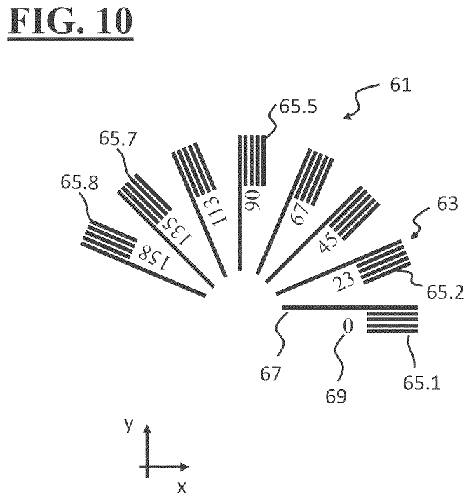

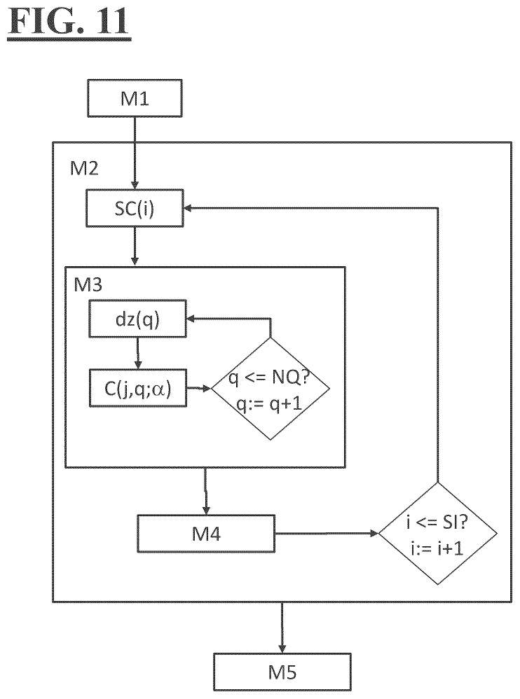

In a further example of the method of calibration according to the fifth embodiment, an absolute calibration of the sensitivity of a variation element 605 or a compensator element 601 or 603 with respect to a wave-front aberration is described. The absolute calibration is performed at a specific test pattern for determination of wave-front aberrations. An example of a test pattern or wave-front detection pattern 61 is shown in FIG. 10. The wave-front detection pattern 61 comprises several repetitive features 63, which are arranged at different rotation angles. The wave-front detection pattern 61 of FIG. 10 comprises eight repetitive features 63, which are arranged at equidistant rotation steps of 22.5°. Each feature 63 is labeled with a label 69, here the rotation angles (0, 23, 45, 67, 90, 113, 135 and 158) is used as label. Each feature 63 comprises a first grid pattern 65 for the determination of a wave-front aberration of the form of an astigmatism. Each feature 63 comprises a second line pattern 67 for the determination of a wave-front aberration of the form of coma. A test wafer is provided with a plurality of identical wave-front detection patterns 61 is provided, with at least one detection pattern 61 arranged in the raster configuration 41 of the plurality of primary charged particle beamlets 3. The method of calibration is further illustrated in FIG. 11.

In a first step M1, the test wafer is aligned in the image plane of the multi-beam charged particle microscope 1, such that a test pattern 61 is arranged in each of the image subfields 29 corresponding to each of the plurality of primary charged particle beamlets 3.

In iteration step M2, the compensator element to be calibrated is set to a first control parameters value SC(1) of a series of predetermined control parameter values SC(i=1 . . . SI). The compensator element can be any compensator of an array element 601 or a global compensator 603. The calibration can also be performed of the variation element 605.

In iteration step M3, a focus series through a predetermined focus interval with focus steps dz(q) with q=1 . . . NQ is performed. At each focus position, digital images are obtained and a plurality of contrast values C(j,q;α) for the regular grid patterns 65 with angle α are determined. In addition, the relative displacement of the center of gravities drα of the line pattern 67 with angle α are determined.

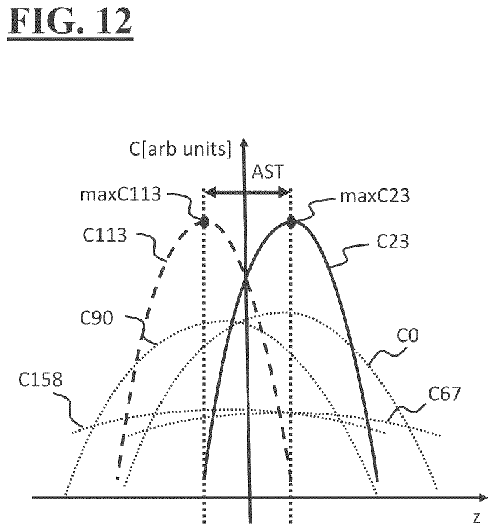

In step M4, for a control parameter value SC(i) the contrast curves through focus are evaluated. First, parabolic contrast curves are fitted to the contrast measurements through the focus stack. An example is illustrated in FIG. 12. FIG. 12 shows the 6 contrast curves C0, C23, C67, C90, C113 and C158 of the first grid patterns 65 at angles 0°, 22.5°, 67.5°, and the second grid patterns 65 at angles 90°, 112.5° and 157.5° perpendicular to the first patterns. Two contrast curves C23 and C113 show a strong image contrast with maximum values maxC23 and maxC23, corresponding to an astigmatism oriented at 22.5° with respect to the x-axis. For the other orientations of the patterns 63, the two line foci 76.1 and 76.2 of an astigmatic beamlet as shown in FIG. 3 are rotated with respect to the line grid 65.2 or 65.7, and are neither oriented perpendicular or parallel to the line grid 65.2 or 65.7. The absolute astigmatism value AST oriented at 22.5° corresponding to the control parameter value SC(i) is then determined by the distance of the two focus positions of the two maximum contrast values. This value is also called the astigmatic focus difference of HV-structures (HV is for horizontal-vertical, meaning two grid patterns oriented perpendicular to each other).

The method steps of M2 through M4 may be repeated until a predetermined sequence of control parameter values SC(i) with I=i . . . SI is achieved. For each control parameter values SC(i=1 . . . SI), the astigmatic focus difference value is determined.

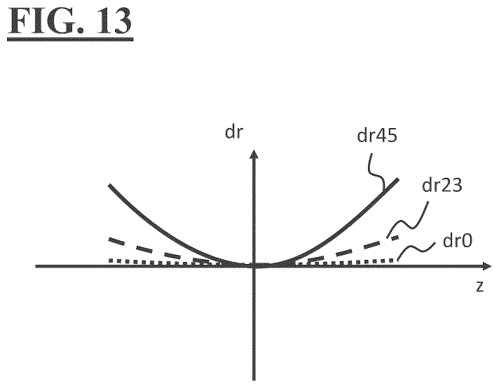

Next, in step M4, also the center positions dr of the line patterns 67 through focus can be analyzed. FIG. 13 is the illustration of a result of the analysis. In this example, the wave-front aberration of interest is not astigmatism, but coma. Due to wave-front aberration of the form of coma, the maximum position dr of a line image drifts through focus and shows a curved line. FIG. 13 illustrates three examples of curved line at the example of the relative displacement drα of a line image through focus position z for the angles α=0°, α=23°, and α=45°. In this example, a coma-aberration oriented under 45° is present.

The change of focus position according step M3 can be performed either by a stage 500 with an actuator to displace the object surface 25 in z-direction or by any other mechanism to change a focus position of the multi-beam charged particle microscope 1.

The method according to FIG. 11 can be performed for a calibration of the absolute sensitivity parameters of a variation element 605 od a compensation element 601 or 603. The method can also be applied to an absolute measurement of a wave-front aberration of a multi-beam charged particle microscope 1 in general.

A method of determining a wavefront aberration of each beamlet of a plurality of J primary charged particle beamlet of a multi-beam charged particle microscope (1), is therefore comprising the steps of: (a) providing for each of the beamlets of the plurality of J primary charge particle beamlets a wave-front detection pattern (61) in an image plane (101) of the multi-beam charged particle microscope (1), each wave-front detection pattern (61) comprising a plurality of repetitive features (63) oriented at different rotation angles a; (b) performing a plurality of measurement of the wave-front detection patterns (61) in a focus series with NQ focus steps q=1 . . . NQ and determining a plurality of contrast values C(j,q;α); (c) approximating a plurality of contrast curves C(j;α) as a function of focus position for each of the beamlets j=1 . . . J and each of the rotation angles α; (d) deriving the maximum values maxC(j;α) for each of the contrast curves C(j;α); and (e) determining a symmetrical wave-front aberration A(j) with a rotational symmetry of even order, such as an stigmatism AST0 or AST45, for each of the beamlets from the maximum difference of two focus-positions of two maximum values maxC(j;α) and maxC(j;α−90) of two repetitive features (63) oriented at 90° with respect to each other.

The method may further comprise the determination of a plurality of relative image displacement dr(j;α) through focus of each of the plurality of repetitive features (63) and determining an asymmetric wave-front aberration with a rotational symmetry of odd order, for example COMA0 or COMA90, for each of the beamlets from the maximum relative image displacement dr through focus.

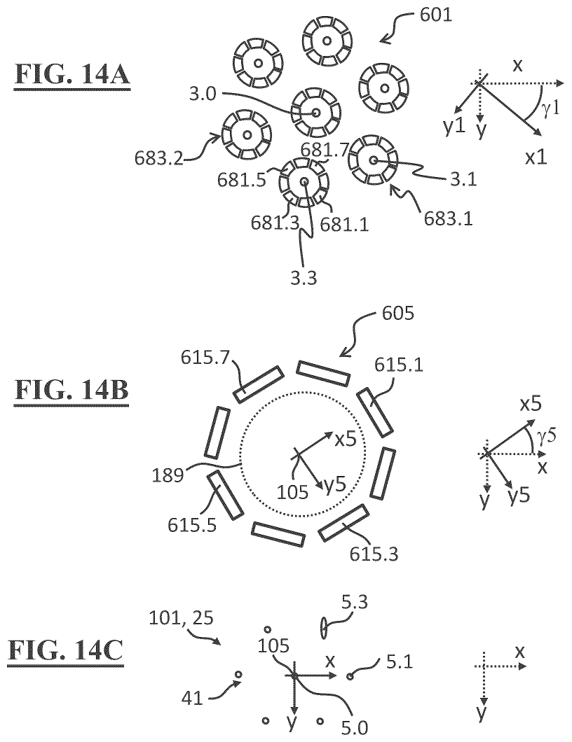

In an example of the embodiments of the disclosure, a rotation of the raster configuration 41 of the plurality of primary beamlets 3 is considered. Such an example in illustrated in FIG. 14. A rotation of the raster configuration 41 can be a result of magneto-optical lens elements, such as field lenses as for example lenses 103.1 and 103.2, the objective lens 102, or other magneto-optical elements. Sometimes, such a rotation of the plurality of J primary charged particle beamlets 3 is called Larmor-rotation. Due to the Larmor rotation, the coordinate systems (x, y) of different multipole elements can have different orientation. In FIG. 14 an example of a first setting point or reference setting point is illustrated. The coordinates systems are chosen as in FIG. 1, with the z-coordinate in propagation direction of the primary charged particle beamlets 3. The rotation between the multi-array elements of the primary multi-beamlet-forming unit 305, comprising the array element of compensators 601 is adjusted such that focus or dwell points 5 (see dwell points 5.0, 5.1 and 5.3 in FIG. 14C) are formed in the raster configuration 41 in the x-y coordinate system of the image plane 101. The dwell points 5 are formed on the surface 25 of a sample, for example the wafer, which is arranged in the image plane 101. FIG. 14A shows the corresponding array of compensator elements 601 in a coordinate system (x1, y1), which is rotated with respect to the sample coordinate system (x, y). FIG. 14B) shows the rotated coordinate system (x5, y5) of a global variation element 605. Next, the rotation will be explained at the example of the compensation of a wave-front aberration AST0 of a primary charged particle beamlet 3.3. With an AST0, the line foci are elongated along x- and y-direction of the image plane 101, which is illustrated highly emphasized at elongated dwell point 5.3, corresponding to beamlet 3.3. According to an example, the wave front aberration AST0 is varied by the variation element 605, in this case by providing a first, positive voltage to the electrodes 615.1 and 615.5, and a second, negative voltage to electrodes 615.3 and 615.7 of the variation element 605 (FIG. 14B). The plurality of primary charged particle beamlets is commonly passing the variation element 605 in the intersection area 189. The variation element 605 is arranged in the coordinate system (x5, y5), which is rotated according to the setting point of the multi-beam charged particle microscope 1. The electrodes 615.1 to 615.8 are oriented in the coordinate system (x5, y5), which is rotated accordingly to vary the wavefront aberration AST0 of the plurality of primary charged particle beamlets. The compensation control signal is then determined and provided to the electrodes 681 of the corresponding compensator element 683.3. For example, a third, positive voltage is provided to the electrodes 681.1 and 681.5, and a fourth, negative voltage is provided to electrodes 681.3 and 681.7 of the compensator element 683.3 of the array of compensation element 601 (FIG. 14A). The method of determining the control signals, as for example the third and fourth voltages, is explained above in the compensation determining CDS and compensation execution steps CES. The electrodes 681.1 to 681.8 are oriented in the coordinate system (x1, y1), which is rotated accordingly to compensate AST0 of the primary beamlet 3.3. Global compensation element 603 (not shown) can be arranged in a coordinate system (x3, y3), which is rotated according to the reference setting point of the multi-beam charged particle microscope 1. The electrodes of the global compensation element 603 (not shown) are oriented in the coordinate system (x3, y3), which is rotated accordingly to compensate the first component of amplitude AG1 with a field dependency of the global compensation element of the wavefront aberration AST0 of the plurality of primary charged particle beamlets.

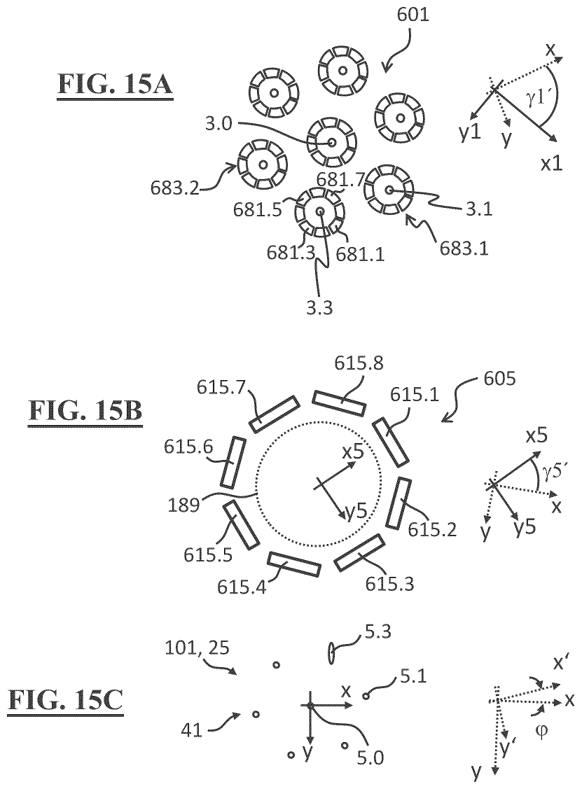

The relative rotation angles between the image plane 101 and the coordinate systems of the array element of compensators 601, the at least one global compensation element 603 and/or the variation element 605 is typically adjusted during manufacturing and calibration of the multi-beam primary charged particle microscope 1 for a predetermined reference first setting point. However, the relative rotation angles may change for different setting points, for example for a second setting point with different magnification, a third setting point with different numerical aperture of the beamlets, or a fourth setting point with different focus distance to the image plane 101. An example is illustrated in FIGS. 15A-15C. According to a different setting point, the raster configuration 41 in the image plane 101 is rotated by angle φ, as illustrated in FIG. 15C. However, the physical implementation of the variation element 605 and the array of raster elements 601 is unchanged. A variation of a wavefront aberration with element 605 is now depending on the relative rotation angle γ5′ between the (x,y) coordinate system of the image plane 101. A variation of an AST0 in image plane 101 can be achieved in two manners.

In a first manner, the variation signal provided to the variation element is adjusted to effect a rotation of the electrostatic variation field in the intersection volume 189. This can be achieved by considering all eight poles of the variation element 605. For example, a positive voltage is provided to the four electrodes 615.1, 615.8, 615.5 and 615.4, and negative voltages are provided to the electrodes 615.2, 615.3, 615.6 and 615.7. With proper adjustment of the voltage levels provided to the electrodes, a field rotation can be achieved. A rotation is further improved by a large number of poles of a multipole element, for example 12 poles or more.

In a second manner, an AST0 is converted in a vector [AST0(0), AST45(0)]. The vector is rotated by a rotation matrix to [AST0(y5′), AST45(γ5′)]=M(γ5′)*[AST0(0), AST45(0)], with rotation matrix M(γ5′). The rotation matrix M is typically specific for each wave-front aberration. In a similar approach, the compensation values GCS or LCS for the compensation elements is computed by considering the rotation matrix with M(Y), with the Larmor rotation angle between the coordinate system of the variation element and the compensation element. The relative rotations between image plane 101 and the coordinate systems of the array element of compensators 601, the at least one global compensation element 603 and/or the variation element 605 are therefore considered by wave-front aberrations as vector-functions with for example [AST0, AST45] or [COMA0, COMA90] according to the order of rotational symmetry of the wave-front aberration. The corresponding rotation angle can be determined during a calibration step and stored in a memory of the control unit 800.

The methods of the second to the fifth embodiment can be implemented in a multi-beam charged particle microscope (1) for either automated application of any of the methods or triggered by a user input. A multi-beam charged particle microscope (1) is therefore configured with a control unit (800), which comprises a processor and a memory with software code and programmed hardware such as FPGAs, which are configured to perform any of the methods according to the second to fifth embodiment. A multi-beam charged particle microscope (1) according to the first embodiment further comprises a multi-beam generating unit (300) for generating during use a plurality of primary charged particle beamlets (3). The multi-beam generating unit (300) further comprises an array of compensation elements (601). The multi-beam charged particle microscope (1) according to the first embodiment further comprises a global compensation element (603) and/or a variation element (605). The control unit (800) is configured to adjust during use the multi-beam charged particle microscope (1) at a setting point and to determine the wavefront aberration amplitudes A(j) of each or the plurality of primary charged particle beamlets (3) at the setting point. The control unit (800) is configured to determine during use a global component AG1 and a residual component Ares(j) of a field dependency of the wave front aberration amplitudes A(j) of the plurality of J primary charged particle beamlets (3). The control unit (800) is further configured to compensate during use the global component AG1 by the global compensation element (603) and the residual components Ares(j) by the array of compensation elements (601). During the determination of the wavefront aberration amplitudes A(j), the control unit (800) is configured to vary a wavefront aberration amplitude of each of the plurality of primary charged particle beamlets (3) with the variation element (605). The global compensation element (603) can be a multipole element comprising at least a first layer of multiple 20) electrostatic or magnetic poles, and the global component AG1 of the field dependency of the wave front aberration amplitudes corresponds to a low order field dependency of the wave front aberration amplitudes effected by the global compensation element (603). The array of compensator components (601) comprises at least a first layer with a plurality of J apertures and multiple electrostatic poles arranged in the circumference of each aperture; and wherein the residual components Ares(j) of the field dependency of the wave front aberration amplitudes is corresponding to a residual wave front aberration, which cannot be compensated with the global compensation element (603). According to the first embodiment, the control unit is further configured to transform during use the wavefront aberration amplitudes determined by the variation of the variation element (605) into normalized sensitivity units and to determine from the residual component of the wavefront aberration amplitudes in normalized sensitivity units a plurality of control signals for the array of compensation elements (601). The control unit (800) is further configured to determine a control signal for the global compensation elements (603) from the global component of the wavefront aberration amplitude AG1 in normalized sensitivity units. In an example, the variation element (605) is given by a deflection scanner (110), or a magnetic correction element (420) of the multi-beam charged particle microscope (1), or is identical to the global compensation element (603) of the multi-beam charged particle microscope (1).

The fast control and the knowledge wave-front aberrations is important not only for a high resolution and a high image contrast, but also for a high image repeatability. Under high image repeatability it is understood that under repeated image acquisition of the same area, a first and a second, repeated digital image is generated, and that the difference between the first and second, repeated digital image is below a predetermined threshold. For example, the difference in image contrast between first and second, repeated digital image is below 10%, such as below 5%. In this way a similar image result is obtained even by repetition of imaging operations. This is important for example for an image acquisition and comparison of similar semiconductor structures in different wafer dies or for comparison of obtained images to representative images obtained from an image simulation from CAD data or from a database or reference images.

### REFERENCE NUMBERS

1 multi-beamlet charged-particle microscope
3 primary electron beamlet(s)
5 primary charged particle beam spot(s)
7 sample or object
9 secondary electron beamlet(s)
11 secondary charged-particle beam path
13 primary charged-particle beam path
15 secondary charged particle image spot(s)
17 image patch
19 image patch overlap
21 center of image patch
25 surface of object 7; wafer surface
27 scan path
29 image subfield
33 first inspection site
35 second inspection site
41 raster configuration
49 setting point
51 second contrast curve fitted to contrast measurements
53 first contrast curve fitted to contrast measurements
55 maximum point of first contrast curve
57 maximum point of second contrast curve
61 wave-front detection pattern
63 repetitive features of wave-front detection pattern
65 regular grid pattern
67 line pattern
69 orientation index
72 first line focus plane
74 circular spot of least confusion
76 line shaped focus
78 second line focus plane
81 first contrast curve
83 second contrast curve
100 object irradiation unit
101 object plane
102 objective lens
103 field lens(es)
105 optical axis
108 beam cross over
110 common deflection system
189 intersection area
200 detection unit
205 Projection system
207 image sensor
208 electrostatic or magnetic lens
209 electrostatic or magnetic lens
210 electrostatic or magnetic lens
212 second cross over
220 secondary electron multi-aperture corrector
222 second common deflection system
300 multi-beamlet generator
301 source
303 collimating lens(es)
305 primary multi-beamlet-forming unit
306.1 first multi-aperture plate
306.2 second and further multi-aperture plates
307 first electrostatic field lens
308 second field lens
309 diverging primary charged particle beam
311 primary charged particle beamlet spots
321 intermediate image plane
390 beam steering multi aperture plate
400 beam divider
420 magnetic correction element
500 sample stage
503 sample charging unit
601 array of compensation elements
603 global compensation element
605 variation element
615 poles
681 electrode(s)
683 multipole elements
685 apertures
687 wiring connection
800 control unit
820 projection system control unit
830 primary beamlet control module

What is claimed is:

1. A multi-beam charged particle microscope, comprising:
a multi-beam generating unit configured to generate a plurality of primary charged particle beamlets, the multi-beam generating unit comprising an array of compensation elements;
a global compensation element;
a variation element; and
a control unit configured to:
adjust the multi-beam charged particle microscope at a setting point;
use the variation element to vary a wavefront aberration amplitude of each of the plurality of primary charged particle beamlets;
determine the wavefront aberration amplitudes of each of the plurality of primary charged particle beamlets at the setting point;
determine a global component and a residual component of a field dependency of the wave front aberration amplitudes of the plurality of primary charged particle beamlets;
compensate the global component by the global compensation element; and
compensate the residual components by the array of compensation elements.

2. The multi-beam charged particle microscope of claim 1, wherein:
the global compensation element comprises a multipole element comprising a first layer of multiple electrostatic or magnetic poles; and
the global component of the field dependency of the wave front aberration amplitudes corresponds to a low order field dependency of the wave front aberration amplitudes effected by the global compensation element.

3. The multi-beam charged particle microscope of claim 1, wherein:
the array of compensator components comprises a first layer comprising a plurality of apertures and multiple electrostatic poles arranged in the circumference of each aperture; and
the residual components of the field dependency of the wave front aberration amplitudes corresponds to a residual wave front aberration, which is not compensated by the global compensation element.

4. The multi-beam charged particle microscope of claim 1, wherein the control unit is configured to:
transform the wavefront aberration amplitudes determined by the variation of the variation element into normalized sensitivity units; and
determine from the residual component of the wavefront aberration amplitudes in normalized sensitivity units a plurality of control signals for the array of compensation elements.

5. The multi-beam charged particle microscope of claim 4, wherein the control unit is configured to determine a control signal for the global compensation elements from the global component of the wavefront aberration amplitude in normalized sensitivity units.

6. The multi-beam charged particle microscope of claim 1, wherein the variation element comprises a member selected from the group consisting of a deflection scanner and a magnetic correction element.

7. The multi-beam charged particle microscope of claim 1, wherein the variation element is identical to the global compensation element.

8. The multi-beam charged particle microscope of claim 1, wherein:
the setting point comprises a deviation of a predetermined rotation of the raster configuration of the plurality of primary charged particle beamlets between the coordinate systems of the image plane, the array of compensator components, the global compensation element and/or the variation element; and
the control unit is configured to compensate a rotation difference of the wave-front aberration between the compensation elements and/or the variation element.

9. A method, comprising:
a) setting a multi-beam microscope to a setting point of an inspection task;
b) varying a wave front aberration of a plurality of primary charged particle beamlets by providing a series of at least three variation control signals to a variation element and measuring a plurality of contrast values at each variation control signal for each of the plurality of primary charged particle beamlets;
c) determining a plurality contrast curves from the plurality of contrast values for each of the plurality of primary charged particle beamlets; and
d) determining a plurality of wave-front aberration amplitudes in normalized sensitivity units at the setting point from the plurality of contrast curves.

10. The method of claim 9, wherein c) comprises, for each of the plurality of primary charged particle beamlets, computing a parabolic, hyperbolic or polynomial approximation to the contrast values.

11. The method of claim 9, wherein d) comprises determining each of plurality of wave-front amplitudes in normalized sensitivity units from: i) a variation control signal at a maximum contrast value divided by a normalized range of the variation element; and/or ii) a parabolic coefficient of the contrast curve.

12. The method of claim 11, further comprising determining the normalized range by determining a maximum control signal and a minimum control signal used to achieve a predetermined variation of the image contrast of at least one of the plurality of primary charged particle beamlets.

13. The method of claim 9, further comprising:
transforming the wave-front aberration amplitudes into a wave-front aberration amplitude vector; and
considering a deviation of a predetermined rotation of the raster configuration of the plurality of primary charged particle beamlets between a coordinate system of an image plane, an array of compensator components, a global compensation element and/or the variation element by multiplying the wave-front aberration amplitude vector with a rotation matrix.

14. A method, comprising:
a) receiving a plurality of wave-front aberration amplitudes of a plurality of primary charged particle beamlets of a multi-beam charged particle microscope in normalized sensitivity units;
b) determining a global component of amplitude in normalized sensitivity units, the global component having a predetermined field dependency of the plurality of the wave-front aberration amplitudes of a global compensation element;
c) determining a residual component of a plurality of residual wave-front amplitudes in normalized sensitivity units;
d) transforming the global component in a global correction signal;
e) transforming the residual component in a plurality of local compensation signals;
f) providing the global correction signal to a global compensating element; and
g) providing the plurality of local compensation signals to an array of compensation elements.

15. The method of claim 14, wherein a) comprises determining the plurality of wave-front aberration amplitudes.

16. The method of claim 15, further comprising determining the plurality of wave-front aberration amplitudes by a method comprising:
varying the wave front aberration of the plurality of primary charged particle beamlets by providing a series of at least three variation control signals to a variation element;
measuring a plurality of contrast values at each variation control signal for each of the plurality of primary charged particle beamlets;
determining a plurality contrast curves from the plurality of contrast values for each of the plurality of primary charged particle beamlets; and
determining a plurality of wave-front aberration amplitudes in normalized sensitivity units from the plurality of contrast curves.

17. The method of claim 16, further comprising computing a parabolic, hyperbolic or polynomial approximation to the contrast values for each of the plurality of primary charged particle beamlets.

18. The method of claim 17, wherein each of the plurality of wave-front amplitudes in normalized sensitivity units is determined from: i) a variation control signal at a maximum contrast value divided by a normalized range of the variation element; and/or ii) a parabolic coefficient of the contrast curve.

19. The method of claim 14, further comprising:
transforming the wave-front aberration amplitudes into a wave-front aberration amplitude vector; and
considering a deviation of a predetermined rotation of the raster configuration of the plurality of primary charged particle beamlets between an array of compensator components, a global compensation element and/or the variation element at the setting point by multiplying the wave-front aberration amplitude vector with a rotation matrix.

20. The method of claim 14, wherein, during d), the global correction signal GCS is obtained from the amplitude in normalized sensitivity units either by multiplying with a predetermined normalized range of the global compensation element or from a predetermined parabolic sensitivity parameter of the global compensation element.
